(19) United States
(12) Patent Application Publication
(10) Pub. No.: US 2012/0152336 A1
(43) Pub. Date: Jun. 21, 2012

(54) AGGREGATE PARTICLES OF TITANIUM DIOXIDE FOR SOLAR CELLS

(75) Inventors: Guozhong Cao, Seattle, WA (US); Xiaoyuan Zhou, Ann Arbor, MI (US); Jun Liu, Richland, WA (US); Zimin Nie, Richland, WA (US); Qifeng Zhang, Seattle, WA (US)

(73) Assignees: PACIFIC NORTHWEST NATIONAL LABORATORY, Richland, WA (US); UNIVERSITY OF WASHINGTON, Seattle, WA (US)

(21) Appl. No.: 13/327,202

(22) Filed: Dec. 15, 2011

Related U.S. Application Data
(63) Continuation of application No. PCT/US2010/038896, filed on Jun. 16, 2010.
(60) Provisional application No. 61/268,768, filed on Jun. 16, 2009.
(60) Provisional application No. 61/230,141, filed on Jul. 31, 2009.
(60) Provisional application No. 61/275,082, filed on Aug. 25, 2009.
(60) Provisional application No. 61/251,999, filed on Oct. 15, 2009.

(51) Int. Cl. H01L 31/0224; B32B 5/16; D02G 3/02; H01B 1/08; B05D 5/12; C01G 23/047; B82Y 40/00; B82Y 30/00

(52) U.S. Cl. 136/254; 427/74; 423/610; 428/401; 428/364; 252/501.1; 977/762; 977/811; 977/896; 977/948

(57) ABSTRACT

Aggregate particles comprising titanium dioxide (TiO₂) nanotubes, methods for making the aggregate particles, photoelectrodes for solar cells including aggregate particles of nanomaterials, methods for making the photoelectrodes, and solar cells that include the photoelectrodes.

### CROSS-REFERENCES TO RELATED APPLICATIONS

This application is a continuation of International Application No. PCT/US2010/038896, filed Jun. 16, 2010, which claims the benefit of U.S. Provisional Application No. 61/268,768, filed Jun. 16, 2009, U.S. Provisional Application No. 61/230,141, filed Jul. 31, 2009, U.S. Provisional Application No. 61/275,082, filed Aug. 25, 2009, and U.S. Provisional Application No. 61/251,999, filed Oct. 15, 2009; each is incorporated herein by reference in its entirety.

### STATEMENT OF GOVERNMENT LICENSE RIGHTS

This invention was made with Government support under Grant No. DE-FG02-07ER46467 awarded by United States Department of Energy and under Grant No. FA9550-06-1-0326 awarded by the Air Force Office of Scientific Research. The Government has certain rights in the invention.

### FIELD OF THE INVENTION

This invention relates to the field of titanium dioxide (TiO₂) nanomaterials, more specifically to the compositions and structures of aggregate particles of TiO₂ nanomaterials, the method of producing said aggregate particles, and the solar cells incorporating said aggregate particles.

### BACKGROUND OF THE INVENTION

The next-generation photovoltaics, often referred to as the third generation solar technologies, have attracted wide attention because of the potential that these technologies may significantly reduce the cost of photovoltaic devices. Non-limiting examples of third generation solar technologies include dye-sensitized solar cells (DSCs) which have now reached commercial production.

Third generation solar technologies typically introduce nanostructures in the photovoltaic layers of solar cells by utilizing nanomaterials to improve the solar-to-electric power conversion efficiency (PCE) of photovoltaic devices. Nanomaterials are characterized by their sizes on the order of approximately 1 Angstrom to 100 μm and are available in a variety of structures including, but not limited to, nanoparticles, nanotubes, nanorods, nanowires, nanobelts, and nanoflowers. Recent advancements in nanotechnologies have lead to numerous high-performance products, including photovoltaic devices. Certain high-performance products comprise nanomaterials where the beneficial effects imparted by the nanomaterials result largely from the significantly higher surface area to volume ratio of the nanomaterials compared to bulk materials that are approximately 1 cm and above in size and whose chemical compositions are identical to those of the nanomaterials.

Among the third generation solar technologies, DSCs that use nanocrystalline TiO₂ as the photoelectrode material have demonstrated a solar-to-electric PCE of over 10% for the laboratory cells and 7-8% for modules. However, further improving the energy conversion efficiency of DSCs is still a challenge. For example and not limitation, the competition between the generation and recombination of photoexcited carriers in DSCs is a bottleneck that inhibits further increasing the solar-to-electric PCE. Accordingly, the design of DSCs may be improved by the development of technologies for enhancing the generation of photoexcited carriers in DSCs while minimizing the recombination of photoexcited carriers.

One possible solution for enhancing the generation of photoexcited carriers in DSCs while minimizing the recombination of photoexcited carriers is to use one-dimensional (1D) nanostructures to provide a direct pathway for the rapid collection of photogenerated electrons and, therefore, reduce the charge recombination. However, such 1D nanostructures seem to be insufficient in the internal surface area and, thus, limit their efficiency to a relatively low level. Examples of those relatively low levels include, but are not limited to, 1.5% for zinc oxide (ZnO) nanowires (Law, M.; Greene, L. E.; Johnson, J. C.; Saykally, R.; Yang, P. D. Nature Materials 2005, 4, 455-459) or 2.25% for coated ZnO (Law, M.; Greene, L. E.; Radenovic, A.; Kuykendall, T.; Liphardt, J.; Yang, P. D. Journal of Physical Chemistry B 2006, 110, 22652-22663), 6.1% for TiO₂ nanotubes (Mor, G. K.; Shankar, K.; Paulose, M.; Varghese, O. K.; Grimes, C. A. Nano Letters 2006, 6, 215-218: Shankar, K.; Bandara, J.; Paulose, M.; Wietasch, H.; Varghese, O. K.; Mor, G. K.; LaTempa, T. J.; Thelakkat, M.; Grimes, C. A. Nano Letters 2008, 8, 1654-1659), and more recently about 7% using TiO₂ nanowires derived from hydrothermal reactions (Wei, M. D.; Konishi, Y.; Zhou, H. S.; Sugihara, H.; Arakawa, H. Journal of the Electrochemical Society 2006, 153, A1232-A1236: Wang, W. L.; Lin, H.; Li, J. B.; Wang, N. Journal of the American Ceramic Society 2008, 91, 628-631) for laboratory cells.

Another way to enhance DSCs is to increase the light-harvesting capability of the DSCs by introducing scatterers into photoelectrode film. Recently, progress has been reported in ZnO DSCs through enhanced light scattering with controlled aggregation of ZnO nanocrystallites. A PCE of 5.6% was achieved with laboratory cells using N3 dyes, more than double the PCE in nanoporous ZnO electrode DSC (Zhang, Q. F.; Chou, T. R.; Russo, B.; Jenekhe, S. A.; Cao, G. Z. Angewandte Chemie-International Edition 2008, 47, 2402-2406: Chou, T. P.; Zhang, Q. F.; Fryxell, G. E.; Cao, G. Z. Advanced Materials 2007, 19, 2588-2592: Zhang, Q. F., Chou, T. P., Russo, B., Jenekhe, S. A., Cao, G. Z., Advanced Functional Materials 2008, 18, 1654-1660: Chou T. P., Zhang, Q. F., Cao, G. Z., Journal of Physical Chemistry C, 2007, 111, 18804-18811).

Superior performance of controlled aggregates of ZnO nanocrystallites over nanomaterials free of agglomeration can be seen, for example, in the PCT application PCT/US09/52531 which discloses a DSC consisting of a photoelectrode comprising aggregates of ZnO nanoparticles.

The improvement in the PCE of DSC comprising the photoelectrodes of controlled aggregates results from the enhanced light scattering caused by the aggregates whose size is comparable to the wavelength of light. Photoelectrodes of controlled aggregates capture incident light more efficiently than photoelectrodes comprising nanomaterials free of agglomeration, while maintaining a very high surface area to volume ratio of photoelectrodes. In addition, improved light capturing by the photoelectrodes enables the reduction in the thickness of the photoelectrodes, thereby reducing the unwanted recombination of photogenerated electrons.

However, the method of forming aggregate particles for DSC photoelectrodes disclosed in PCT/US09/52531 is applicable only to the synthesis of aggregates of ZnO nanoparticles and therefore is not readily extended to the production of aggregate particles from the nanomaterials of other types of structures and/or compositions such as TiO₂ nanoparticles and nanotubes. Furthermore, PCT/US09/52531 discloses only a method wherein the aggregates of ZnO nanoparticles are synthesized by a solvothermal method as colloidal solutions directly from a Zn containing precursor in a solvent wherein the ZnO nanoparticles spontaneously assemble into aggregates during a carefully controlled reaction.

Thus, there remains a need for a technology to produce the aggregate particles of nanomaterials tailored for photovoltaic applications designed to maximize the beneficial effects imparted by nanomaterials in photovoltaic devices such as DSCs.

### SUMMARY OF THE INVENTION

In certain embodiments, aggregate particles of TiO₂ nanomaterials for a solar cell are provided. In certain such embodiments, the aggregate particles improve the solar-to-electric power conversion efficiency of said solar cell over said TiO₂ nanomaterials. In certain such embodiments, the improvement in the solar-to-electric power conversion efficiency results from enhanced light scattering by the aggregate particles. In certain embodiments, the TiO₂ nanomaterials are nanotubes. In certain embodiments, the TiO₂ nanomaterials are nanoparticles. In certain embodiments, the TiO₂ nanomaterials comprise substantially crystalline structures. In certain embodiments, the solar cell is a dye-sensitized solar cell. In certain embodiments, the TiO₂ nanomaterials range in size between 1 Angstrom to 100 μm. In certain embodiments, the TiO₂ nanomaterials range in size between 1 nm-1 μm. In certain embodiments, the TiO₂ nanomaterials range in size between 10 nm-100 nm. In certain embodiments, the diameter of the aggregate particles is between 1 nm to 100 μm. In certain embodiments, the diameter of the aggregate particles is between 10 nm to 10 μm. In certain embodiments, the diameter of the aggregate particles is between 100 nm to 1 μm. In certain embodiments, the surface area of the aggregate particles is between 1 cm²/g to 1,000 m²/g. In certain embodiments, the surface area of said aggregate particles is between 50 cm²/g to 1,000 m²/g. In certain embodiments, the surface area of said aggregate particles is between 1 m²/g to 1,000 m²/g. In certain embodiments, the aggregate particles comprise interconnected pores of 0.1 nm to 10 μm in diameter. In certain embodiments, aggregate particles comprise interconnected pores of 0.1 nm to 1 μm in diameter. In certain embodiments, the aggregate particles comprise interconnected pores of 0.1 nm to 100 nm in diameter. In certain embodiments, the aggregate particles have a plurality of sizes. In certain embodiments, the aggregate particles are combined with TiO₂ precursor or nanomaterials. In certain embodiments, the nanomaterials are nanotubes and the solar cell is a dye-sensitized solar cell.

In certain embodiments, the TiO₂ nanomaterials are nanotubes and the nanotubes comprise a tube diameter of between 0.1 nm to 10 μm and a tube length of 0.1 nm to 100 μm. In certain embodiments, the TiO₂ nanomaterials are nanotubes and the nanotubes comprise a tube diameter of between 1 nm to 1 μm and a tube length of 0.1 nm to 100 μm. In certain embodiments, the TiO₂ nanomaterials are nanotubes and the nanotubes comprise a tube diameter of between 0.1 nm to 10 μm and a tube length of 1 nm to 10 μm. In certain embodiments, the TiO₂ nanomaterials are nanotubes and the nanotubes comprise a tube diameter of between 1 nm to 1 μm and a tube length of 1 nm to 10 μm.

In certain embodiments, the aggregate particles comprise a diameter of between 0.1-10 μm; and a surface area of between 1-1,000 m²/g.

In certain embodiments, the TiO₂ nanomaterials are nanoparticles and diameter of the nanoparticles is 0.1 nm to 1 μm. In certain embodiments, the TiO₂ nanomaterials are nanoparticles and diameter of the nanoparticles is 1 nm to 100 nm.

In certain embodiments, the TiO₂ nanomaterials comprise substantially crystalline structures and the crystalline structures are the anatase phase of TiO₂. In certain embodiments, the TiO₂ nanomaterials comprise substantially crystalline structures and the crystalline structures are the rutile phase of TiO₂. In certain embodiments, the TiO₂ nanomaterials comprise substantially crystalline structures and the crystalline structures are a mixture of anatase and rutile phases of TiO₂.

In certain embodiments, the aggregate particles comprise nanotubes, and the nanotubes comprise sodium. In certain embodiments, the nanotubes comprise less than 10 percent sodium as measured weight percent. In certain embodiments, the nanotubes comprise less than 1 percent sodium as measured weight percent.

In certain embodiments, a method of forming aggregate particles of TiO₂ nanomaterials for a solar cell is provided. In certain such embodiments, a method of forming aggregate particles of TiO₂ nanomaterials comprises selecting a TiO₂ precursor. In certain such embodiments, a method of forming aggregate particles of TiO₂ nanomaterials comprises transforming said precursor to TiO₂ nanomaterials. In certain such embodiments, a method of forming aggregate particles of TiO₂ nanomaterials comprises effecting the formation of aggregate particles from said TiO₂ nanomaterials. In certain such embodiments, a method of forming aggregate particles of TiO₂ nanomaterials comprises effecting the formation of aggregate particles from said TiO₂ nanomaterials. In certain embodiments, the aggregate particles improve the solar-to-electric power conversion efficiency of said solar cell over said TiO₂ nanomaterials. In certain such embodiments, the improvement in the solar-to-electric power conversion efficiency results from enhanced light scattering by the aggregate particles. In certain embodiments, the TiO₂ nanomaterials are nanotubes. In certain embodiments, the TiO₂ nanomaterials are nanoparticles. In certain embodiments, the formation of aggregate particles is effected in the presence of ethanol. In certain embodiments, the TiO₂ nanomaterials are nanotubes and the formation of aggregate particles is effected by contacting said TiO₂ nanomaterials to ethanol and then contacting said TiO₂ nanomaterials to hydrochloric acid. In certain embodiments, the formation of aggregate particles is effected from an emulsion of said TiO₂ nanomaterials. In certain embodiments, the formation of aggregate particles is effected from an emulsion of said TiO₂ nanomaterials by a hydrothermal method.

In certain embodiments, a method of forming aggregate particles of TiO₂ nanomaterials for a solar cell is provided. In certain such embodiments, a method of forming aggregate particles of TiO₂ nanomaterials comprises selecting a TiO₂ precursor. In certain such embodiments, a method of forming aggregate particles of TiO₂ nanomaterials comprises transforming said precursor to a sol. In certain such embodiments, a method of forming aggregate particles of TiO₂ nanomaterials comprises preparing a water-in-oil emulsion combining said sol with said emulsion. In certain such embodiments, a method of forming aggregate particles of TiO₂ nanomaterials comprises effecting the formation of aggregate particles by a hydrothermal method. In certain such embodiments, a method of forming aggregate particles of TiO₂ nanomaterials comprises recovering said aggregate particles. In certain embodiments, the aggregate particles improve the solar-to-electric power conversion efficiency of the solar cell over said TiO₂ nanomaterials. In certain embodiments, the formation of aggregate particles is effected by a hydrothermal method. In certain embodiments, the formation of aggregate particles is effected by a hydrothermal method in the presence of templates. In certain embodiments, the templates comprise carbon spheres. In certain embodiments, the formation of aggregate particles is effected by a solvothermal method.

In certain embodiments, a method of forming a photoelectrode of a solar cell comprising aggregate particles of TiO₂ nanomaterials is provided. In certain such embodiments, a method of forming a photoelectrode of a solar cell comprises selecting a TiO₂ precursor. In certain such embodiments, a method of forming a photoelectrode of a solar cell comprises transforming said TiO₂ precursor into a first kind of TiO₂ nanomaterials. In certain such embodiments, a method of forming a photoelectrode of a solar cell comprises effecting the formation of aggregate particles from said first kind of TiO₂ nanomaterials. In certain such embodiments, a method of forming a photoelectrode of a solar cell comprises depositing said aggregate particles on a substrate. In certain such embodiments, the aggregate particles improve the solar-to-electric power conversion efficiency of the solar cell over said first TiO₂ nanomaterials.

In certain embodiments, a method of forming a photoelectrode of a solar cell comprising aggregate particles of TiO₂ nanomaterials is provided. In certain such embodiments, a method of forming a photoelectrode of a solar cell comprises selecting a TiO₂ precursor. In certain such embodiments, a method of forming a photoelectrode of a solar cell comprises transforming said TiO₂ precursor into a first kind of TiO₂ nanomaterials. In certain such embodiments, a method of forming a photoelectrode of a solar cell comprises effecting the formation of aggregate particles from said first kind of TiO₂ nanomaterials. In certain such embodiments, a method of forming a photoelectrode of a solar cell comprises selecting a second kind of TiO₂ nanomaterials. In certain such embodiments, a method of forming a photoelectrode of a solar cell comprises depositing said aggregate particles and said second kind of TiO₂ nanomaterials on a substrate. In certain such embodiments, a method of forming a photoelectrode of a solar cell comprises heat treating said substrate. In certain such embodiments, the aggregate particles improve the solar-to-electric power conversion efficiency of said solar cell over said first or second kind of TiO₂ nanomaterials.

In certain embodiments, a method of forming a photoelectrode of a solar cell comprising aggregate particles of TiO₂ nanomaterials is provided. In certain such embodiments, a method of forming a photoelectrode of a solar cell comprises selecting a TiO₂ precursor. In certain such embodiments, a method of forming a photoelectrode of a solar cell comprises transforming said TiO₂ precursor into a first kind of TiO₂ nanomaterials. In certain such embodiments, a method of forming a photoelectrode of a solar cell comprises effecting the formation of aggregate particles from said first kind of TiO₂ nanomaterials. In certain such embodiments, a method of forming a photoelectrode of a solar cell comprises depositing said aggregate particles on a substrate. In certain such embodiments, a method of forming a photoelectrode of a solar cell comprises heat treating said substrate. In certain such embodiments, the aggregate particles improve the solar-to-electric power conversion efficiency of the solar cell over said first TiO₂ nanomaterials.

In certain embodiments, a method of forming a photoelectrode of a solar cell comprising aggregate particles of TiO₂ nanomaterials is provided. In certain such embodiments, a method of forming a photoelectrode of a solar cell comprises selecting a TiO₂ precursor. In certain such embodiments, a method of forming a photoelectrode of a solar cell comprises transforming said TiO₂ precursor into a first kind of TiO₂ nanomaterials. In certain such embodiments, a method of forming a photoelectrode of a solar cell comprises effecting the formation of aggregate particles from said first kind of TiO₂ nanomaterials. In certain such embodiments, a method of forming a photoelectrode of a solar cell comprises selecting a second kind of TiO₂ nanomaterials. In certain such embodiments, a method of forming a photoelectrode of a solar cell comprises depositing said aggregate particles and said second kind of TiO₂ nanomaterials on a substrate. In certain such embodiments, the aggregate particles improve the solar-to-electric power conversion efficiency of said solar cell over said first or second kind of TiO₂ nanomaterials.

In certain embodiments, improvement in the solar-to-electric power conversion efficiency results from enhanced light scattering by said aggregate particles. In certain embodiments, aggregate particles comprise nanotubes. In certain embodiments, aggregate particles comprise nanoparticles.

In certain embodiments, the thickness of photoelectrode is 1 nm to 1 mm. In certain embodiments, the thickness of photoelectrode is 10 nm to 100 μm. In certain embodiments, the thickness of photoelectrode is 1 μm to 50 μm.

In certain embodiments, the surface area of the photoelectrode is 1 cm²/g to 1,000 m²/g. In certain embodiments, the surface area of the photoelectrode is 50 cm²/g to 1,000 m²/g. In certain embodiments, the surface area of the photoelectrode is 1 m²/g to 1,000 m²/g.

In certain embodiments, the solar cell is a dye-sensitized solar cell. In certain embodiments, the second kind of TiO₂ nanomaterials are nanoparticles. In certain embodiments, the aggregate particles and the second kind of nanomaterials are deposited on the substrate as a mixture. In certain embodiments, the aggregate particles and the second kind of nanomaterials are sequentially deposited on the substrate as a separate layer. In certain embodiments, the second kind of nanomaterials are first deposited on the substrate. In certain embodiments, the second kind of nanomaterials are nanoparticles.

In certain embodiments, a photoelectrode of a solar cell comprising aggregate particles of TiO₂ nanomaterials is provided. In certain such embodiments, the aggregate particles improve the solar-to-electric power conversion efficiency of the solar cell over the TiO₂ nanomaterials.

In certain embodiments, a photoelectrode of a solar cell comprising aggregate particles of TiO₂ nanomaterials is provided. In certain such embodiments, the synthesis of the aggregate particles comprises selecting a TiO₂ precursor. In certain such embodiments, the synthesis of the aggregate particles comprises transforming said TiO₂ precursor into a first kind of TiO₂ nanomaterials. In certain such embodiments, the synthesis of the aggregate particles comprises effecting the formation of aggregate particles from said first kind of TiO₂ nanomaterials. In certain such embodiments, the synthesis of the aggregate particles comprises depositing said aggregate particles on a substrate. In certain such embodiments, the aggregate particles improve the solar-to-electric power conversion efficiency of the solar cell over said first TiO₂ nanomaterials.

In certain embodiments, a photoelectrode of a solar cell comprising aggregate particles of TiO₂ nanomaterials is provided. In certain such embodiments, the synthesis of the aggregate particles comprises selecting a TiO₂ precursor. In certain such embodiments, the synthesis of the aggregate particles comprises transforming said TiO₂ precursor into a first kind of TiO₂ nanomaterials. In certain such embodiments, the synthesis of the aggregate particles comprises effecting the formation of aggregate particles from said first kind of TiO₂ nanomaterials. In certain such embodiments, the synthesis of the aggregate particles comprises selecting a second kind of TiO₂ nanomaterials. In certain such embodiments, the synthesis of the aggregate particles comprises depositing said aggregate particles and said second kind of TiO₂ nanomaterials on a substrate. In certain such embodiments, the synthesis of the aggregate particles comprises heat treating said substrate. In certain such embodiments, the aggregate particles improve the solar-to-electric power conversion efficiency of said solar cell over said first or second kind of TiO₂ nanomaterials.

In certain embodiments, a photoelectrode of a solar cell comprising aggregate particles of TiO₂ nanomaterials is provided. In certain such embodiments, the synthesis of the aggregate particles comprises selecting a TiO₂ precursor. In certain such embodiments, the synthesis of the aggregate particles comprises transforming said TiO₂ precursor into a first kind of TiO₂ nanomaterials. In certain such embodiments, the synthesis of the aggregate particles comprises effecting the formation of aggregate particles from said first kind of TiO₂ nanomaterials. In certain such embodiments, the synthesis of the aggregate particles comprises depositing said aggregate particles on a substrate. In certain such embodiments, the synthesis of the aggregate particles comprises heat treating said substrate. In certain such embodiments, the aggregate particles improve the solar-to-electric power conversion efficiency of the solar cell over said first TiO₂ nanomaterials.

In certain embodiments, a photoelectrode of a solar cell comprising aggregate particles of TiO₂ nanomaterials is provided. In certain such embodiments, the synthesis of the aggregate particles comprises selecting a TiO₂ precursor. In certain such embodiments, the synthesis of the aggregate particles comprises transforming said TiO₂ precursor into a first kind of TiO₂ nanomaterials. In certain such embodiments, the synthesis of the aggregate particles comprises effecting the formation of aggregate particles from said first kind of TiO₂ nanomaterials. In certain such embodiments, the synthesis of the aggregate particles comprises selecting a second kind of TiO₂ nanomaterials. In certain such embodiments, the synthesis of the aggregate particles comprises depositing said aggregate particles and said second kind of TiO₂ nanomaterials on a substrate. In certain such embodiments, the aggregate particles improve the solar-to-electric power conversion efficiency of said solar cell over said first or second kind of TiO₂ nanomaterials.

In certain embodiments, improvement in the solar-to-electric power conversion efficiency results from enhanced light scattering by said aggregate particles. In certain embodiments, the aggregate particles comprise nanotubes. In certain embodiments, the aggregate particles comprise nanoparticles. In certain embodiments, the solar cell is a dye-sensitized solar cell.

In certain embodiments, the thickness of photoelectrode is 1 nm to 1 mm. In certain embodiments, the thickness of photoelectrode is 10 nm to 100 μm. In certain embodiments, the thickness of photoelectrode is 1 μm to 50 μm.

In certain embodiments, the surface area of the photoelectrode is 1 cm²/g to 1,000 m²/g. In certain embodiments, the surface area of the photoelectrode is 50 cm²/g to 1,000 m²/g. In certain embodiments, the surface area of the photoelectrode is 1 m²/g to 1,000 m²/g.

In certain embodiments, the second kind of TiO₂ nanomaterials are nanoparticles. In certain embodiments, the aggregate particles and the second kind of nanomaterials are deposited on the substrate as a mixture. In certain embodiments, the aggregate particles and the second kind of nanomaterials are sequentially deposited on the substrate as a separate layer. In certain embodiments, the second kind of nanomaterials are first deposited on the substrate. In certain embodiments, the second kind of nanomaterials are nanoparticles.

These and other features of the present teachings are set forth herein.

### DESCRIPTION OF THE DRAWINGS

The foregoing aspects and many of the attendant advantages of this invention will become more readily appreciated as the same become better understood by reference to the following detailed description, when taken in conjunction with the accompanying drawings.

FIG. 1 shows scanning electron microscope (SEM) and transmission electron microscopy (TEM) images. The SEM image reveals that the materials are made of 2 to 4 μm sized, oval shaped aggregates (FIG. 1A). In the TEM image, the 1D nanostructure becomes clearly visible (FIG. 1B).

FIG. 2 shows X-ray diffraction (XRD) patterns of samples of nanotubes as-prepared and heat treated at 400, 500, and 600° C., respectively.

FIG. 3 shows TEM images of the materials processed under different conditions: (3A) to (3B) Nanotubes calcined at 400° C.; (3C) Nanoparticles after 600° C. calcinations; (3D) A TEM image of the nanotubes at 500° C.; (3E) to (3F) High resolution TEM images at 500° C. The insets in (3A), (3C), and (3D) correspond to the selected area electron diffraction (SAED) patterns.

FIG. 4 shows the specific surface area of micron-sized aggregate particles of TiO₂ nanotubes as a function of annealing temperatures as determined by means of nitrogen sorption isotherms. The specific surface area is reduced from 424 m²/g for the sample before calcination, to 255 m²/g annealed at 400° C., to 147 m²/g at 500° C., and to 50 m²/g at 600° C.

FIG. 5 shows UV-Vis absorption spectra of the photoelectrodes made of respective TiO₂ nanotube aggregate particles and commercial grade TiO₂ nanoparticles (Degussa Aeroxide P25) before dye loading. The photoelectrode comprising P25 shows a typical intrinsic absorption at the wavelength shorter than 390 nm, but the nanotube aggregate photoelectrode having nominal absorption throughout the entire wavelength due to strong light scattering.

FIG. 6 shows the current-voltage curves of DSCs with photoelectrodes made of different TiO₂ nanotube aggregate particles: (6A) TiO₂ nanotube aggregate particles calcined at different temperatures and (6B) TiO₂ nanotube aggregate particles calcined at 500° C., but with different film thickness.

FIGS. 7A-7C show TiO₂ aggregate particles synthesized by the emulsion method (7A and 7B) and the XRD pattern (7C).

FIGS. 8A and 8B show TiO₂ aggregate particles synthesized by the hydrothermal method (8A) and the XRD pattern (8B).

FIG. 9 shows SEM images of (9A) TiO₂ nanocrystalline film (Sample I) and (9B) TiO₂ aggregate particle film (Sample II).

FIG. 10 shows XRD patterns of TiO₂ nanocrystalline film and aggregate particle film.

FIG. 11 shows SEM images of films of nanocrystallites admixed with aggregate particles in a ratio of (11A) 3:1 (Sample III), (11B) 1:1 (Sample IV), and (11C) 1:3 (Sample V). The drawing of (11D) schematically shows the embedded structure of TiO₂ aggregate particles in nanocrystalline film and generation of light scattering.

FIGS. 12A and 12B show optical absorption spectra of TiO₂ nanocrystalline film (12A) and aggregate particle film (12B).

FIG. 13 shows a comparison of optical transmittance of TiO₂ nanocrystalline film (Sample I), aggregate particle film (Sample II), and the films of nanocrystallites mixed with aggregate particles in different ratios: 3:1 (Sample III), 1:1 (Sample IV), and 1:3 (Sample V). The inset shows a magnified view of the spectra of Samples II, V, and IV.

FIG. 14 shows a comparison of DSC solar-to-electric power conversion efficiencies of TiO₂ nanocrystalline film, aggregate particle film and the films of nanocrystallites combined with aggregate particles in different ratios.

FIG. 15 shows pore size distribution of TiO₂ aggregate particles.

FIG. 16 shows the XRD pattern of the TiO₂ nanotubes before and after annealing at 500° C.

FIG. 17 shows SEM images of the aggregate structures. (17A) is a low magnification image. (17B) is a high magnification image. No detectable differences were observed between the as prepared and annealed samples.

FIG. 18 shows nitrogen sorption isotherms of the TiO₂ nanotube before and after annealing at 500° C.

FIG. 19 shows the photocurrent density-voltage curve of DSC comprising the aggregate particles of TiO₂ nanotubes.

FIG. 20 shows the TEM images of TiO₂ nanotubes: (20A) high magnification image of as prepared TiO₂ nanotube; (20B) high magnification image of TiO₂ nanotube after annealing at 500° C.; (20C) and (20D) low magnification images of as prepared TiO₂ nanotube; and (20E) low magnification image of TiO₂ nanotube after annealing at 500° C.

FIG. 21 is a schematic illustration of a representative solar cell of the invention including a photoelectrode of the invention.

FIG. 22A is a schematic illustration of a representative photoelectrode of the invention. A dye-sensitized solar cell photoelectrode having a layer of nanoparticles is shown in FIG. 22B.

### DETAILED DESCRIPTION OF THE INVENTION

The present invention provides aggregate particles comprising titanium dioxide (TiO₂) nanotubes, methods for making the aggregate particles, photoelectrodes for solar cells including aggregate particles of nanomaterials, methods for making the photoelectrodes, and solar cells that include the photoelectrodes.

In one aspect, the present invention provides aggregate particles comprising titanium dioxide (TiO₂) nanotubes. Representative nanotubes comprise substantially crystalline structures including the anatase phase, the rutile phase, and mixtures of the anatase phase and the rutile phase.

In one embodiment, the nanotubes range in size from about 1 Angstrom to about 100 μm. In one embodiment, the nanotubes have a length from about 0.1 nm to 100 μm. In one embodiment, the nanotubes have a diameter from about 0.1 nm to 10 μm.

In one embodiment, the aggregate particles have a diameter of from about 1 nm to about 100 μm. In one embodiment, the aggregate particles have a surface area from about 1 cm²/g to about 1,000 m²/g. In one embodiment, the aggregate particles include interconnecting pores having a diameter from about 0.1 nm to 10 μm. In certain embodiments, the aggregate particles further include a titanium dioxide nanomaterial or a titanium dioxide nanomaterial precursor. Representative nanomaterials include nanotubes, nanoparticles, and mixtures thereof.

In another aspect of the invention, a method of forming aggregate particles of titanium dioxide nanotubes is provided.

In one embodiment, the method comprises:

(a) transforming a titanium dioxide nanomaterial precursor to a titanium dioxide nanotube; and

(b) forming aggregate particles of titanium dioxide nanotubes from the titanium dioxide nanomaterial precursor.

In one embodiment, forming the aggregate particles comprises contacting with ethanol. In one embodiment, forming the aggregate particles comprises contacting with hydrochloric acid after contacting with ethanol. In another embodiment, transforming a titanium dioxide nanomaterial precursor to a titanium dioxide nanotube comprises forming an emulsion of the titanium dioxide nanomaterial precursor.

In one embodiment, forming aggregate particles of titanium dioxide nanotubes comprises a hydrothermal method.

In another embodiment, a method for forming aggregate particles of titanium dioxide nanomaterials is provided.

In one embodiment, the method comprises:

(a) transforming a titanium dioxide nanomaterial precursor to a titanium dioxide nanomaterial sol;

(b) combining the sol with an oil to provide an emulsion; and

(c) forming aggregate particles of titanium dioxide nanomaterials from the emulsion by a hydrothermal method.

In one embodiment, forming aggregate particles from the emulsion comprises a hydrothermal method. In another embodiment, forming aggregate particles from the emulsion comprises a solvothermal method.

In a further embodiment, a method for forming aggregate particles of titanium dioxide nanomaterials is provided.

In one embodiment, the method comprises:

(a) transforming a titanium dioxide nanomaterial precursor to a titanium dioxide nanomaterial; and

(b) forming aggregate particles of titanium dioxide nanomaterials from the titanium dioxide nanomaterial precursor in the presence of a template, preferably a carbon sphere template.

In the above methods, representative nanomaterials include nanotubes, nanoparticles, and mixtures thereof.

In a further aspect, the invention provides methods of forming a photoelectrode of a solar cell. In one method, a plurality of the aggregate particles of the invention are deposited on a substrate. In one embodiment, the aggregate particles comprise titanium dioxide nanotubes. In another embodiment, the aggregate particles comprise titanium dioxide nanoparticles. In another embodiment, the aggregate particles comprise titanium dioxide nanotubes and titanium dioxide nanoparticles.

The methods can further comprising depositing a titanium dioxide nanomaterial on the substrate. Representative nanomaterials include nanotubes, nanoparticles, and mixtures thereof. In one embodiment, the nanomaterial is deposited on the substrate before the aggregate particles are deposited. In one embodiment, the nanomaterial is deposited after the aggregate particles are deposited on the substrate. In one embodiment, the aggregate particles are combined with the nanomaterials and deposited together on the substrate.

The methods can further comprise heat treating the substrate.

In a further aspect of the invention, a photoelectrode for a solar cell is provided.

In one embodiment, the photoelectrode comprises:

(a) a substrate; and

(b) a layer on a surface of the substrate, wherein the layer comprises aggregate particles of the invention.

In one embodiment, the photoelectrode comprises:

(a) a substrate; and

(b) a layer on a surface of the substrate, wherein the layer comprises aggregate particles of titanium dioxide nanomaterials.

Representative nanomaterials include nanotubes, nanoparticles, and mixtures thereof.

In certain embodiment, the nanomaterial forms a layer on the substrate, forms a layer on the layer comprising aggregate particles, or is combined with the aggregate particles in the aggregate particle layer.

In one embodiment, the photoelectrode has a surface area from about 1 cm²/g to 1,000 cm²/g. In one embodiment, the photoelectrode has a thickness from about 1 nm to about 1 mm.

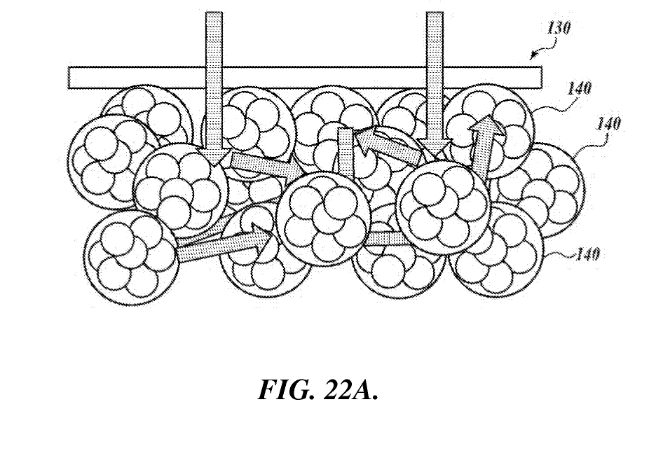

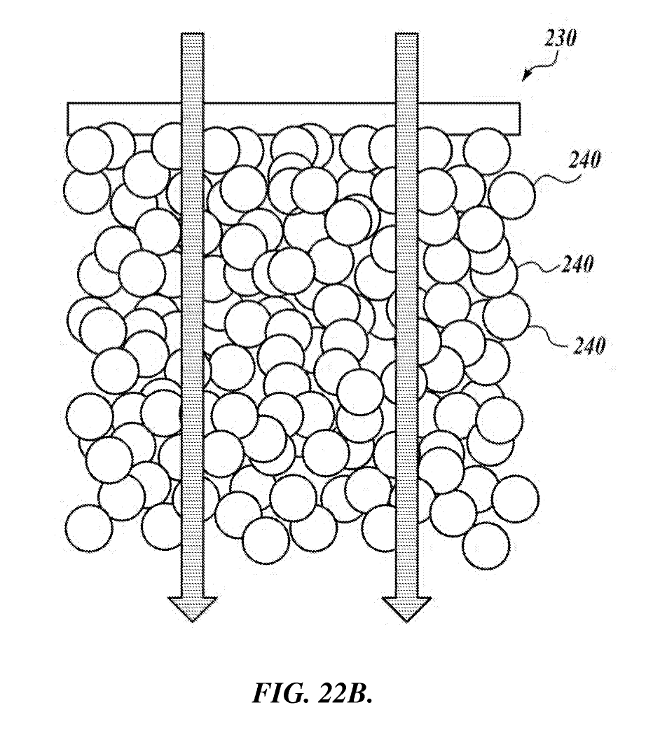

In representative photoelectrodes of the invention, the layer of aggregate particles provides enhanced light scattering within the layer compared to a photoelectrode comprising a layer of titanium dioxide nanomaterials in non-aggregated particle form. Compare, for example FIGS. 22A and 22B. In these figures, the arrows represent light particles. A schematic illustration of a representative photoelectrode of the invention is shown in FIG. 22A. Referring to FIG. 22A, representative photoelectrode 130 includes a substrate and a layer comprising aggregate particles of the invention 140. A dye-sensitized solar cell photoelectrode having a layer of nanoparticles is shown in FIG. 22B. Referring to FIG. 22B, photoelectrode 230 includes a substrate and a layer comprising individual nanoparticles 240.

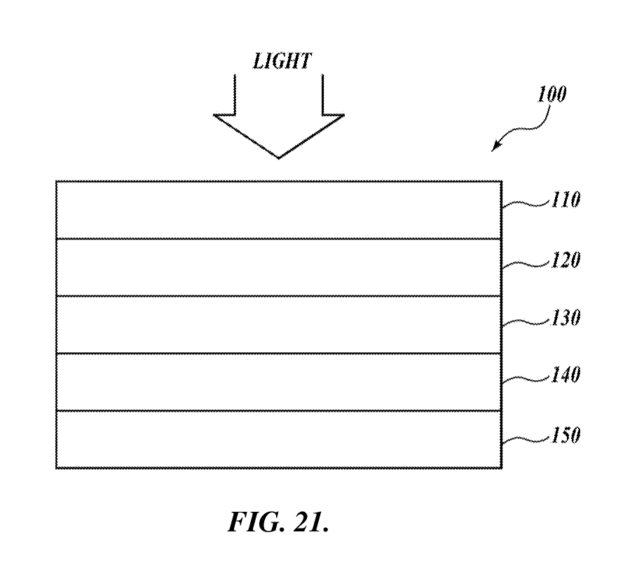

In another aspect, the invention provides a solar cell comprising a photoelectrode of the invention. In one embodiment, the solar cell is a dye-sensitized solar cell. FIG. 21 provides a schematic illustration of a representative solar cell of the invention including a photoelectrode of the invention. Referring to FIG. 21, solar cell 100 includes substrate (plastic or glass) 100, charge collecting layer 120, photoelectrode 130 and associated dye, electrolyte layer 140, and counter electrode 150.

Unless otherwise defined, all technical and scientific terms used herein have the same meaning as commonly understood by one of ordinary skill in the art. Publications, patent applications, patents, and other references mentioned herein are incorporated by reference in their entirety.

Unless specific definitions are provided, the nomenclatures utilized in connection with, and the laboratory procedures and techniques of, analytical chemistry, synthetic organic and inorganic chemistry, and chemical processing described herein are those well known and commonly used in the art. Standard techniques may be used for chemical syntheses, chemical analysis, and material processing and handling.

In this application, the use of the singular includes the plural unless specifically stated otherwise. In this application, the use of “or” means “and/or” unless stated otherwise. In the context of a multiple dependent claim, the use of “or” refers back to more than one preceding independent or dependent claim in the alternative only. The use of the term “including”, as well as other forms, such as “includes” and “included”, is not limiting. Also, terms such as “element” or “component” encompass both elements and components comprising one unit and elements and components that comprise more than one subunit unless specifically stated otherwise.

The term “TiO₂ precursors” refers to the compositions comprising the monomeric compounds which polymerize into TiO₂ nanomaterials. Examples of TiO₂₂ precursors include, but are not limited to, titanium tetraisopropoxide, titanium tetrabutoxide, titanium tetraethoxide, titanium tetraoxychloride, titanium tetrachloride and titanium n-propoxide.

The term “nanomaterials” refers to materials on the order of 1 Angstrom to 100 μm. In certain embodiments, the range of nanomaterials is anything less than 100 nm. In certain embodiments, the range of nanomaterials is 1 nm-1 μm. In certain embodiments, the range of nanomaterials is 10-100 nm.

In certain embodiments, nanomaterials comprise substantially crystalline structures. In certain embodiments, nanomaterials comprise the anatase phase of TiO₂. In certain embodiments, nanomaterials comprise the rutile phase of TiO₂. In certain embodiments, nanomaterials comprise the anatase and rutile phases of TiO₂.

The term “aggregate particles” refers to particles on the order of 1 nm to 100 μm which are produced by agglomerating nanomaterials. In certain embodiments, the diameter of aggregate particles is 1 nm 100 μm. In certain embodiments, the diameter of aggregate particles is 10 nm-10 μm. In certain embodiments, the diameter of aggregate particles is 100 nm-1 μm.

In certain embodiments, the surface area per unit mass of aggregate particles is comparable to that of the constituent nanomaterials.

In certain embodiments, aggregate particles may comprise TiO₂ precursors and/or nanomaterials in a residual amount. In certain embodiments, aggregate particles are deliberately combined with TiO₂ precursors and/or nanomaterials. In certain embodiments, aggregate particles have a plurality of sizes.

The term “hydrothermal method” refers to a thermally induced reaction carried out in an aqueous solution. In certain embodiments, the reaction may be carried out at ambient pressure (e.g., under a refluxing condition). In certain embodiments, the reaction may be carried out at elevated pressure (e.g., in an autoclave).

The term “solvothermal method” refers to a thermally induced reaction carried out in solutions substantially free of water.

The term “dye-sensitized solar cell” (DSC) refers to a photovoltaic device based on a photoelectrochemical system comprising a pair of anode and cathode to define a cell which is filled with an electrolyte wherein the anode consists of a semiconducting layer coated with a photosensitizer which absorbs the light and emits an electron.

The term “photoelectrode” refers to a semiconducting layer in the anode of DSC. Photoelectrode is a porous film comprising TiO₂ aggregate particles and, optionally, TiO₂ nanomaterials such as TiO₂ nanoparticles substantially free of agglomeration. The photoelectrode film features a very large surface area and consists of or includes submicron-sized TiO₂ aggregate particles.

The present invention is directed to aggregate particles of inorganic nanomaterials, their methods of production, and the devices and compositions that incorporate those aggregate particles. In certain embodiments, the compositions and structures of said aggregate particles are precisely controlled to optimize end-use performance. More specifically, the present invention is directed to the aggregate particles of nanomaterials which improve the solar-to-electric PCE of DSCs by the enhanced light scattering.

The improvement in the solar-to-electric PCE of DSC comprising the controlled aggregate particles of this invention as the photoelectrode materials results from the enhanced light scattering caused by the aggregates whose size is comparable to the wavelength of light. Photoelectrodes of controlled aggregates capture incident light more efficiently than photoelectrodes comprising nanomaterials free of agglomeration, while maintaining a very high surface area to volume ratio of photoelectrodes for assuring high dye loading. In addition, improved light capturing by the photoelectrodes enables the reduction in the thickness of the photoelectrodes, thereby reducing the unwanted recombination of photogenerated electrons.

In certain embodiments, nanomaterials are TiO₂ nanomaterials. In certain embodiments, the TiO₂ nanomaterials are TiO₂ nanoparticles or nanotubes.

TiO₂ nanomaterials may be synthesized by the methods well-known in the art by, for examples, sol-gel method, hydrothermal method, or flame pyrolysis of TiO₂ precursol such as titanium tetraisopropox or titanium tetrachloride. In certain embodiments, commercially available TiO₂ nanomaterials may be used.

In certain embodiments, the aggregate particles of nanomaterials are characterized by sizes on the order of 1 nm to 100 μm and those aggregate particles comprise nanomaterials on the order of 1 Angstrom to 100 μm as the constituent materials. In certain embodiments, the aggregate particles of nanomaterials are characterized by sizes on the order of 10 nm to 100 μm and those aggregate particles consist of nanomaterials on the order of 1 nm to 1 μm as the constituent materials. In certain embodiments, the aggregate particles of nanomaterials are characterized by sizes on the order of 100 nm to 1 μm and those aggregate particles consist of nanomaterials on the order of 10 nm to 100 nm as the constituent materials.

In certain embodiments, the aggregate particles of TiO₂ nanomaterials are powdery free-flowing materials. In certain such embodiments, the aggregate particles of TiO₂ nanomaterials are dispersible, detached from each other, and the aggregate particles of TiO₂ nanomaterials do not agglomerate under ambient conditions.

In certain embodiments, the constituent nanomaterials that comprise aggregate particles may take the form of, but are not limited to the forms of, nanoparticles, nanotubes, nanorods, nanowires, nanobelts, and nanoflowers.

In certain embodiments, compositions of aggregate particles of TiO₂ nanomaterials for a solar cell are provided. In certain embodiments, a solar cell is a DSC.

In certain embodiments, the TiO₂ precursor is titanium tetraisopropoxide.

In certain embodiments, aggregate particles are porous particles comprising: aggregate diameter of 1 nm to 100 μm; pore diameter of 1 nm to 10 μm; and surface area of 1 cm²/g to 1,000 m²/g. In certain embodiments, aggregate particles are porous particles comprising: aggregate diameter of 100 nm to 100 μm; pore diameter of 0.1 nm to 1 μm; and surface area of 50 cm²/g to 1,000 m²/g.

In certain embodiments, aggregate particles comprise TiO₂ nanotubes. In certain embodiments, TiO₂ nanotubes comprise: tube diameter of 0.1 nm to 10 μm; and tube length of 0.1 nm to 100 μm. In certain embodiments, TiO₂ nanotubes comprise; tube diameter of 1 nm to 1 μm; and tube length of 1 nm to 10 μm.

In certain embodiments, aggregate particles comprise TiO₂ nanoparticles. In certain embodiments, the range of diameter of TiO₂ nanoparticles is 0.1 nm to 1 μm. In certain embodiments, the range of diameter of TiO₂ nanoparticles is 1 nm to 100 nm.

In certain embodiments, a method of synthesizing the aggregate particles of TiO₂ nanomaterials is provided. In certain embodiments, the method of synthesizing the aggregate particles of TiO₂ nanomaterials for a solar cell comprises the steps of:

a) selecting a TiO₂ precursor;

b) transforming said precursor to TiO₂ nanomaterials;

c) effecting the formation of aggregate particles from said TiO₂ nanomaterials; and

d) recovering said aggregate particles.

In certain embodiments, nanomaterials are in the form of sol or dry particles of TiO₂ nanoparticles. In certain embodiments, nanomaterials are in the form of aqueous sol of colloidal TiO₂ nanoparticles. In certain embodiments, nanomaterials are in the form of dry nanotubes.

In certain embodiments, TiO₂ nanoparticles are synthesized by the hydrolysis of TiO₂ precursor by a hydrothermal method. Examples of hydrothermal methods include the method comprising the steps of: formation of TiO₂ sol by combining titanium tetraisopropoxide, deionized (DI) water, and acetate acid; and hydrothermal growth of resulting TiO₂ sol in an autoclave at elevated temperature.

In certain embodiments, nanomaterials are synthesized by a sol-gel method from precursors. Examples of sol-gel methods include the hydrolysis of TiO₂ precursor such as titanium tetraisopropoxide at ambient temperature and pressure.

In certain embodiments, the formation of aggregate particles is effected by an emulsion method.

In certain embodiments, the formation of aggregate particles is effected by a hydrothermal method within the emulsion comprising the steps of.

a) selecting a TiO₂ precursor;

b) transforming said precursor to a sol;

c) preparing a water-in-oil emulsion;

d) combining said sol with said emulsion;

e) effecting the formation of aggregate particles by a hydrothermal method; and

f) recovering said aggregate particles.

In this method, the hydrolysis reaction of TiO₂ precursor yielding TiO₂ nanoparticles proceeds within the confined spherical water droplets of emulsions under a hydrothermal condition such as the hydrothermal treatment in an autoclave, leading to the formation of aggregate particles of TiO₂ nanoparticles. In place of synthesizing a sol from a TiO₂ precursor, commercially available TiO₂ nanomaterials may be used to prepare a sol of TiO₂ nanomaterials in step b) above. The size of aggregate particles may be controlled by carefully adjusting the solid content of sol and the size of water droplets. In certain embodiments, the formation of aggregate particles is effected by converting TiO₂ particulates on the order of 10 nm to 100 μm in diameter to mesoporous particles by a hydrothermal method. TiO₂ particulates may be synthesized from a stock solution comprising titanium tetraisopropoxide and ethylene glycol. The resulting stock solution is added into acetone containing a small amount of DI water. After the reaction, white precipitate of TiO₂ particles is collected and washed with DI water. The resulting precipitate was subjected to a hydrothermal treatment in an autoclave with DI water or immersed in acidic water under a reflux condition to form mesoporous particles.

In certain embodiments, the formation of aggregate particles is effected by a hydrothermal method in the presence of templates such as carbon spheres. In one example of such a method, the synthesis of TiO₂ aggregate particles starts from the preparation of a TiO₂ sol by adding titanium alkoxide into an aqueous solution containing hydrochloric acid, ethanol, and sugar or more specifically sucrose. The molar ratio of titanium alkoxide: hydrochloric acid: sucrose: ethanol: water in the sol is, for example, 0.03: 0.5: 0.02: 0.4:1. The sol is sequentially transferred to an autoclave for hydrothermal growth at 100-250° C. for 10 h. After the reaction, the precipitate which comprises TiO₂ and carbon formed from sucrose is washed with DI water. The product is then heated at 500° C. for 3 h in air to remove the carbon from the product and finally obtain a powder of TiO₂ aggregates. In this method, TiO₂ nanoparticles precipitate and agglomerate on the porous carbon spheres which are simultaneously formed from sucrose during the hydrothermal growth.

In certain embodiments, the formation of aggregate particles is effected by a solvothermal method. Examples of solvothermal method includes a solvothermal reaction of titanium alkoxide tin diethylene glycol (DEG) under an acidic condition. The most significant innovation of the solvothermal method is the use of non-volatile solvent such as DEG as the solvent to provide a temperature higher than 100° C. for the hydrolysis of titanium alkoxide, enabling the hydrolysis reaction to be carried out at elevated temperature under ambient pressure without utilizing an autoclave.

In certain embodiments, the process of the invention uses a hydrothermal process to create aggregate particles of TiO₂ nanomaterials. In certain embodiments, the formation of aggregate particles is effected by agglomerating nanomaterials.

In certain embodiments, a method of forming aggregate particles of TiO₂ nanotubes is provided. In a typical synthesis of TiO₂ nanotubes, TiO₂ nanoparticles are added into an aqueous solution of sodium hydroxide. After stirring for overnight, the resulting suspension is transferred to a Teflon-lined autoclave and heated to 120° C. to 150° C. for over 12 hours. To form the aggregate particles of TiO₂ nanotubes, the product is first washed in ethanol with stirring and separated by centrifuge. The ethanol washed sample is then dried and acid-washed in HCl solutions. In this method, the formation of aggregate particles of TiO₂ nanotubes is effected by contacting said nanotubes to ethanol.

In certain embodiments, commercially available nanomaterials can be utilized because the provided process to effect the formation of aggregate particles is applicable to the formation of aggregate particles from pre-synthesized nanomaterials of variable compositions and structures.

The TiO₂ aggregate particles of this invention may be used alone or in combination with the conventional TiO₂ nanoparticles utilized in the manufacturing DSCs. In certain embodiments, this invention relates to the method of forming a photoelectrode of a solar cell comprising aggregate particles of TiO₂ nanomaterials comprising the steps of:
a) selecting a TiO₂ precursor;
b) transforming said TiO₂ precursor to a first kind of TiO₂ nanomaterials;
c) effecting the formation of aggregate particles from said first kind of TiO₂ nanomaterials;
d) optionally, selecting a second kind of TiO₂ nanomaterials;
e) depositing said aggregate particles and said second kind of TiO₂ nanomaterials on a substrate; and
f) optionally, heat treating said substrate.

In certain embodiments, a photoelectrode of solar cell is formed from a mixture of TiO₂ nanoparticles and TiO₂ aggregate particles. In certain embodiments, a photoelectrode of solar cell is formed by depositing TiO₂ nanoparticles first and then TiO₂ aggregate particles in that order.

In certain embodiments, this invention relates to the functional materials and devices which comprise the aggregate particles of TiO₂ nanomaterials wherein the performance of functional materials and devices comprising said aggregate particles are superior to that of functional materials and devices comprising the nanomaterials free of agglomerations.

In certain embodiments, this invention relates to a photoelectrode of solar cell. In certain embodiments, said photoelectrode comprises the aggregate particles of this invention and the nanomaterials substantially free of agglomeration.

In certain embodiments, this invention relates to the photoelectrode of DSC. In certain embodiments, the thickness of the photoelectrode of DSC is 1 nm to 1 mm. In certain embodiments, the thickness of the photoelectrode of DSC is 10 nm to 100 μm. In certain embodiments, the thickness of the photoelectrode of DSC is 1 μm to 50 μm.

In certain embodiments, this invention relates to the DSCs comprising the aggregate particles of TiO₂ nanomaterials as the photoelectrode materials.

Synthesis and Characterization of DSCs Comprising Aggregate Particles of TiO₂ Nanotubes containing Na impurity. Synthesis and characterization of micron-sized aggregates of TiO₂ nanotubes: The synthesis of aggregate particles of TiO₂ nanotubes may begin with the synthesis of TiO₂ nanoparticles from TiO₂ precursors such as titanium tetraisopropoxide. Alternatively, commercially available TiO₂ nanoparticles may be utilized as the starting materials. TiO₂ nanoparticles are first grown into nanotubes which are then formed into aggregate particles according to the procedures described herein.

Commercial grade, TiO₂ (Degussa Aeroxide P25) nanoparticles were a gift from Degussa Corp (Parsippany, N.J.), and used without further purification or treatment. Ethanol alcohol, sodium hydroxide (NaOH) and hydrochloride acid (HCl) were purchased from Alfa Aesar. In a typical synthesis of titanate nanotubes, 1.0 g of Degussa Aeroxide P25 powder was added into an 80 mL aqueous solution of 10M sodium hydroxide. After stirring for overnight, the resulting suspension was transferred to a Teflon-lined autoclave and heated to 120° C. to 150° C. for over 12 hours. The product was washed in ethanol with stirring for 30 min and separated by centrifuge at 5000 rpm for 20 min. The ethanol washed sample was then dried and acid-washed in HCl solutions (0.05 M to 0.2 M) for three times. Finally, the nanotubes were calcined in air from 400° C. to 600° C. for 2 hours.

Solar cells testing: The preparation of DSC and the testing were carried out according to previously published protocols (X. J. Feng, K. Shankar, O. K. Varghese, M. Paulose, T. J. Latempa and C. A. Grimes, Nano Lett., 8 (2008) 3781-3786: Y. J. Lee, D. S. Ruby, D. W. Peters, B. B. McKenzie and J. W. P. Hsu, Nano Lett., 8 (2008) 1501-1505: T. C. Monson, M. T. Lloyd, D. C. Olson, Y. J. Lee and J. W. P. Hsu, Adv. Mater., 20 (2008) 4755: A. Usami, Chem. Phys. Lett., 277 (1997) 105-108). The photoelectrode films were fabricated on fluorinated tin oxide (FTO) glass using a drop-cast method. The films were annealed at 450° C. in air to remove any residual organic matter from TiO₂ the TiO₂ films. The films were then sensitized by immersing into 0.5 mM ethanolic solution of commercially available N719 dye (Solterra Fotovoltaico SA, Switzerland) for 24 hours. The films were then rinsed with ethanol to remove the additional dye. The electrolyte in this study was made up of a liquid admixture containing 0.5 M tetrabutylammonium iodide, 0.1 M lithium iodide, 0.1 M iodine and 0.5 M 4-ter-butylpyridine in acetonitrile. The photovoltaic behaviors were characterized when the cell devices were irradiated by simulated AM1.5 sunlight with output power of 100 mWcm-2. An Ultraviolet Solar Simulator (Model 16S, Solar Light Co., Philadelphia, Pa.) with a 200 W Xenon Lamp Power Supply (Model XPS 200, Solar Light Co., Philadelphia, Pa.) was used as the light source, and a Semiconductor Parameter Analyzer (4155A, Hewlett-Packard, Japan) was used to measure the current and voltage.

Structural Characterization: Transmission electron microscopy (TEM) study was performed on a JEOL JSM-2010 microscope at 200 kV. X-ray diffraction (XRD) patterns were recorded on a Philips Xpert X-ray diffractometer using Cu Kα radiation at λ=1.54 Å. N2 adsorption-desorption data were collected using a Quantachrome autosorb automated gas sorption system.

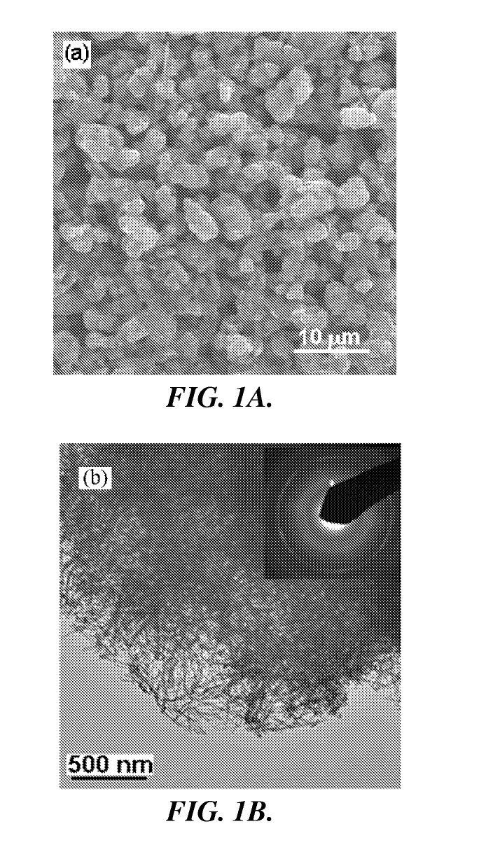

FIG. 1 is the scanning electron microscope (SEM) and TEM images showing certain features of the aggregate structures. The SEM image reveals that the materials are made of 2 to 4 μm sized, oval shaped aggregates (FIG. 1A). In the TEM image, the 1D nanostructure becomes clearly visible (FIG. 1B). Ethanol treatment appears to have played a role in the formation of the aggregated structures. Small aggregates of layer structures and poorly defined tubes were observed without the ethanol wash. Many dense nanowires were observed right after the ethanol wash. The nanotubes became prominent after the subsequent acid wash.

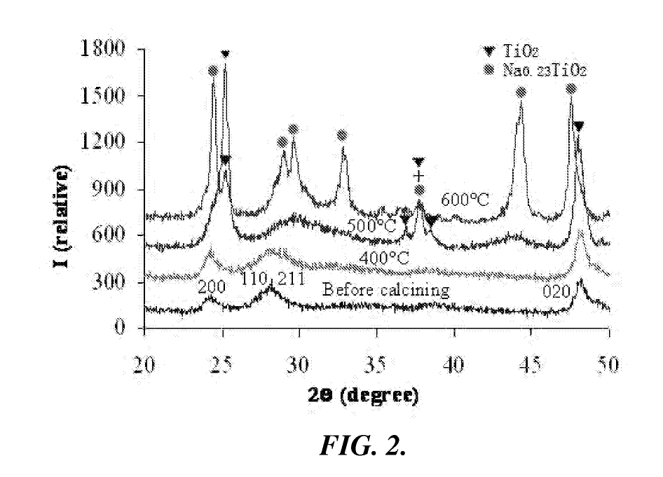

TEM, the selected area electron diffraction (SAED), and XRD studies revealed that the nanotubes prepared prior to thermal annealing at elevated temperatures typically possessed hydrogen titanate structure, consistent with the literature data, but not all the sodium was removed as indicated in the energy dispersive spectrum (EDS) of the sample calcined at 500° C. . FIG. 2 shows XRD patterns of samples as-prepared and heat treated at 400, 500, and 600° C., respectively. The nanotube diffraction pattern before calcination is indexed according to the H₂Ti₃O₇ structure (H₂Ti₃O₇, monoclinic, C2/m, a=1.603, b=0.375, c=0.919 nm, β=101.45°). The sample annealed at 500° C. possesses very strong anatase peaks, suggesting the predominance of anatase phase. The sample annealed at 600° C. shows the presence of mostly Na0.23TiO₂, again suggesting the incomplete removal of sodium during the ethanol and subsequent acid washing.

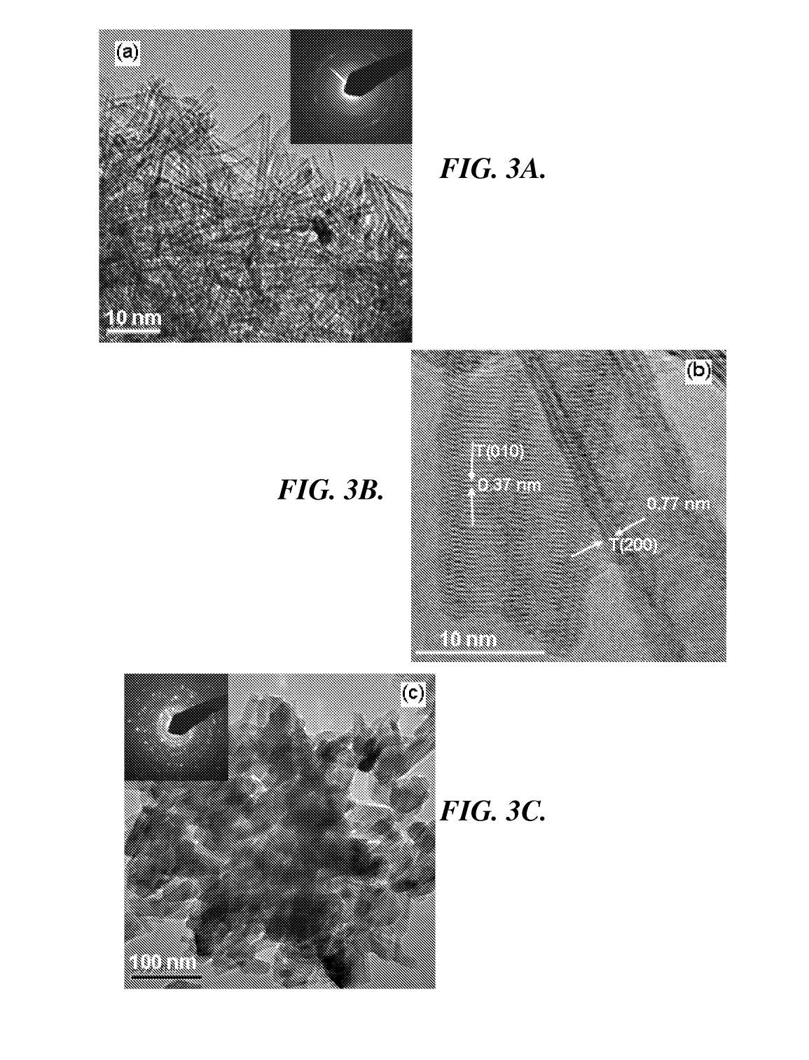

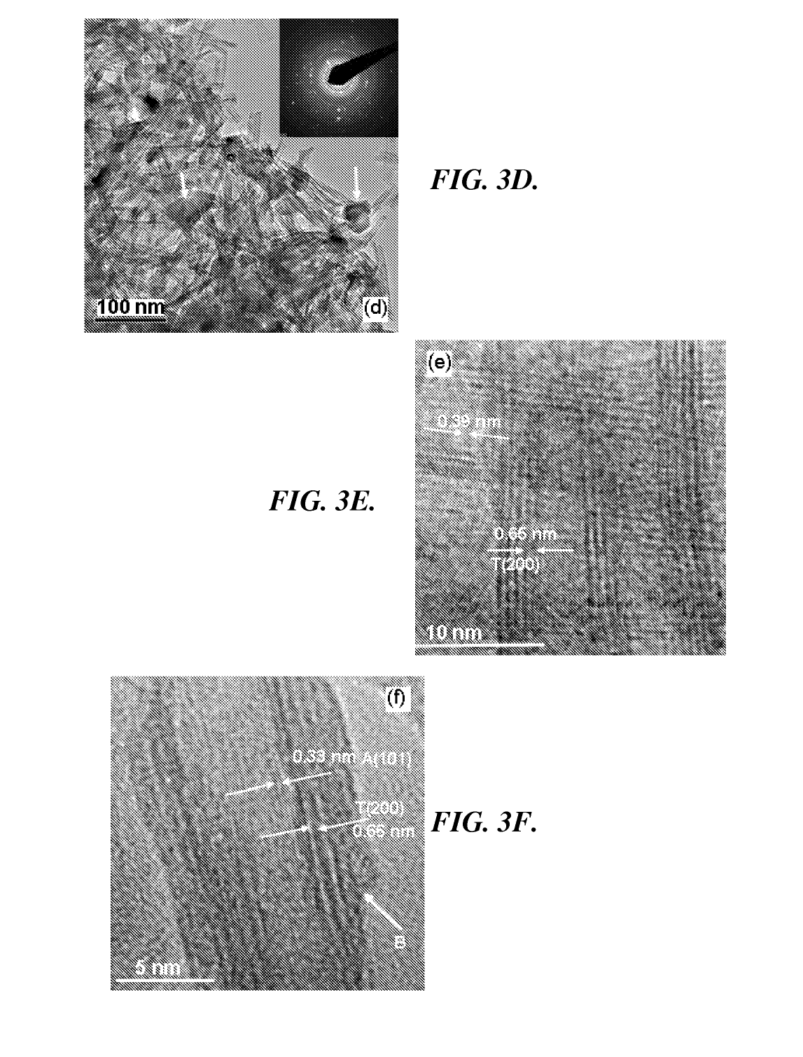

TEM observation further confirms that the detailed structure is sensitive to the calcination temperatures. FIGS. 3A to 3B are TEM images of a sample calcined at 400° C. The inset in FIG. 3A is the selected area electron diffraction (SAED) pattern as expected from the H₂Ti₃O₇ structure. The nanotubes grow along the [010] orientation. In the high resolution TEM image (FIG. 3B), the tubular walls, and two typical lattice planes including (200) planes parallel to the tube direction and (010) planes perpendicular to the tube direction, are resolved. When the sample is subjected to annealing at 600° C., the nanotube structures collapsed into nanoparticles as shown in FIG. 3C. The SAED pattern is different, suggesting that the titanate nanotubes were transformed into a mixture of sodium titanium oxide (Na_{0.23}TiO₂, PDF#22-1404) and anatase TiO₂. FIGS. 3D to 3F are the TEM images from a sample calcined at 500° C. A higher magnification TEM image (FIG. 3D) showed that most of the nanotube structures were retained, with the formation of some anatase nanoparticles as indicated by the arrows. The SAED pattern showed that in addition to the strong continuous ring patterns expected from the nanotubes, many strong diffraction spots were observed due to the formation of the anatase phase. The preservation of the continuous nanotube structures was evident in the high resolution TEM image (FIG. 3E). Both the lattice planes perpendicular and parallel to nanotube axes were resolved, but the lattice fringes corresponding to the (200) plane of the titanate were decreased from 0.77 nm to about 0.65 nm. FIG. 3F shows the high resolution image of one nanotube. Here, part of the wall structure in region B began to peel off, suggesting that the nanotube structure began to degrade. Much thinner lattice fringes were observed parallel to the tube axis. The lattice constant is about 0.34 nm, consistent with the (101) plane of anatase as the commonly observed anatase lattice plane. Therefore, the 500° C. calcined sample represents a partially transformed material that still retains most of the nanotube structure.

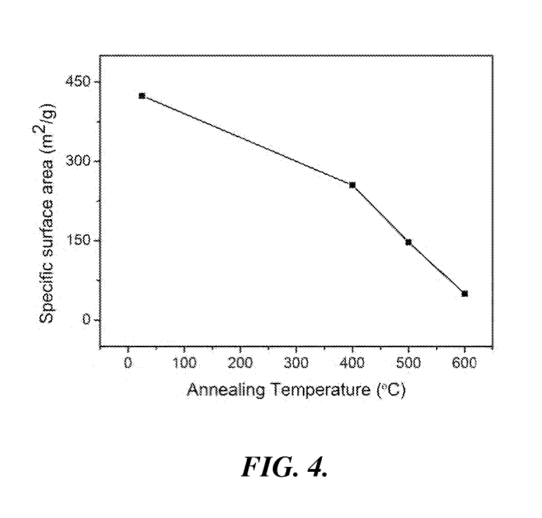

The specific surface areas of micron-sized aggregates of TiO₂ nanotubes are also different after different treatments as shown in FIG. 4. The surface areas changed from 424 m²/g for the sample before calcination, to 255 m²/g annealed at 400° C., to 147 m²/g at 500° C., and to 50 m²/g at 600° C. Such appreciable reduction in specific surface area with an increased annealing temperature suggested a change in the microstructure of the nanotube aggregates, which qualitatively corroborates well with the SEM and TEM observations presented in FIGS. 3a-3f and discussed above. The reduction of specific surface area from 147 m²/g in the sample annealed at 500° C. to 50 m²/g in the sample annealed at 600° C. could be attributed to the collapse of nanotubes to nanoparticles as revealed by TEM (FIG. 3C). There is no definite explanation for the reduction of specific surface area from 424 to 255 and then to 147 m²/g in the samples without thermal annealing, and the samples annealed at 400° C. and 500° C., respectively. However, SEM, TEM, SAED, and XRD analyses all revealed the changes in crystal structure and morphology. One possible explanation is that the phase transition is accompanied by a reduction of specific surface area, driven by a need to reduce the surface energy.

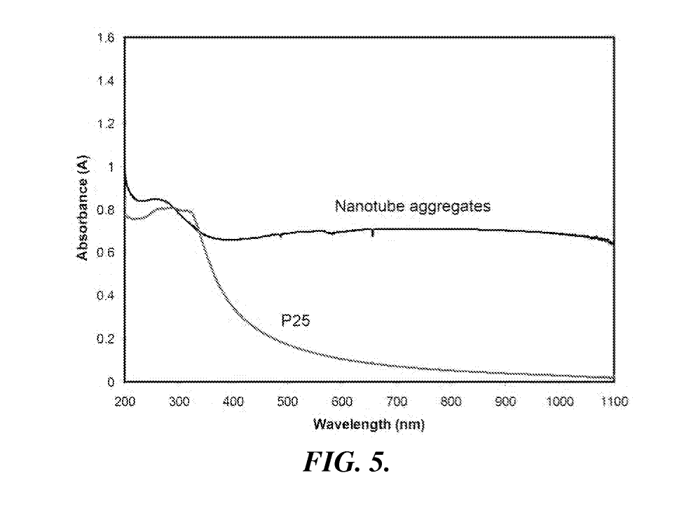

The micron-sized aggregates of TiO₂ nanotubes are very similar to those reported in ZnO, thus may well serve as light scatterers to enhance light harvesting. The light scattering properties of the aggregates are revealed in the UV absorption spectrum, which shows a typical intrinsic absorption below 390 nm (FIG. 5), and a continuous broad, high background in the visible region due to the scattering effect of the micron-sized agglomerates. In comparison, TiO₂ nanoparticles, such as P25, only show the intrinsic absorption without much scattering in the high wave length region. It is also worth noting that the aggregates of TiO₂ nanotubes possess noticeably higher specific surface area, e.g., ˜147 m²/g in the samples annealed at 500° C., than the conventional TiO₂ nanoparticles, typically <90 m²/g. Such high specific surface area facilitates more dye-loading, assuming other conditions are kept the same, and thus promises a higher power conversion efficiency.

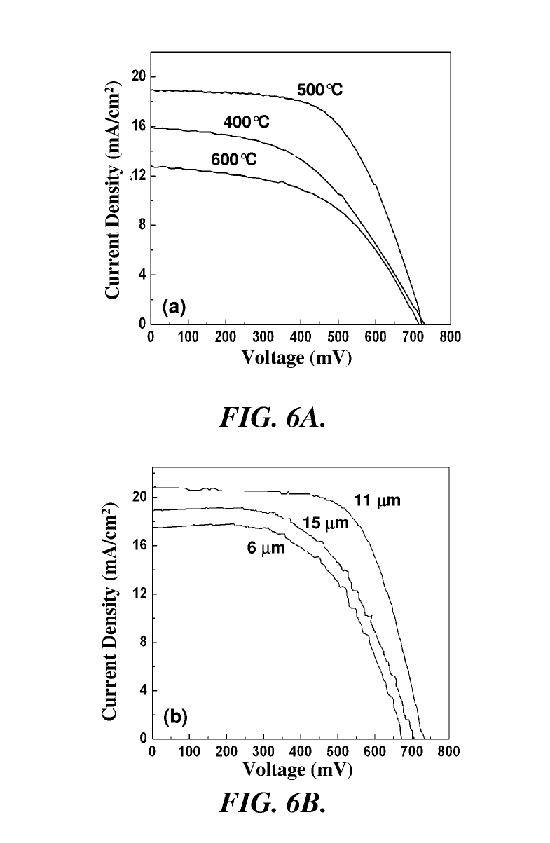

The TiO₂ nanotube solar cells were characterized by measuring the current-voltage behavior while the cells were irradiated by AM 1.5 simulated sunlight with a power density of 100 mW/cm². FIG. 6 shows typical current density versus voltage curves of the different samples. The results from the samples calcined at different temperatures are shown in FIG. 6A.

Table 1 summarizes the open-circuit voltages, the short-circuit current densities, the fill factors, and the overall energy conversion efficiencies for all three samples.

TABLE 1
Open-circuit voltages, short-circuit current densities, fill factors,
and overall power conversion efficiencies for all three samples annealed
at different temperatures and with different film thickness.

| | | V_{oc} | J_{sc} | Vₘₐₓ | Jₘₐₓ | FF | |
|---|---|---|---|---|---|---|---|
| Sample | | (mv) | (Ma/cm²) | (mv) | (mA/cm²) | (%) | η |
| 400° | C. | 730 | 15.9 | 450 | 12.1 | 47 | 5.4 |
| 500° | C. | 720 | 18.7 | 485 | 16.6 | 60 | 8.0 |
| 600° | C. | 710 | 12.8 | 480 | 9.7 | 51 | 4.7 |
| 6 | μm | 670 | 17.5 | 449 | 15.1 | 57 | 6.8 |
| 11 | μm | 730 | 20.8 | 518 | 19.1 | 66 | 9.9 |
| 15 | μm | 700 | 18.8 | 459 | 16.4 | 57 | 7.5 |

Among these, the 500° C. calcined sample had the highest short circuit current (18.7 mA/cm²), and the highest power conversion efficiency (8.0%), with a 60% fill factor. Although the sample from a lower temperature treatment had a higher surface area and better-defined nanotube structures, the efficiency was not as high, likely because the titanate phase itself does not have the optimum properties for DSCs. At much higher temperature, all of the nanotube structures collapsed, and the advantage of the nanotubes was lost, again resulting in a lower efficiency.

The efficiency can be further improved by optimizing the materials parameters. FIG. 6B compares the current density versus voltage curves of 500° C. calcined samples with different film thickness. The corresponding experimental results are also shown in the last three rows in Table 1. Varying the film thickness from 6 μm to 11 μm increased the short circuit current density from 17.5 to 20.8 mA/cm² and PCE from 6.8% to 9.9%. Correspondingly, the fill factor increased from 57% to 66%. However, further increase of the thickness caused a significant drop in the efficiency. The optimum thickness of 11 μm may be related to the diffusion length of the electrons in TiO₂. Below certain critical thickness, the increase in thickness increased the light absorption capability, and therefore the PCE. Beyond this threshold thickness, the transport of the electrons became difficult, and the PCE was reduced. There was also a slight variation of open-circuit voltage in three samples shown in Table 1. Theoretically, the open-circuit voltage is dependent on the materials and, thus, would be the same for all the samples. However, such variation in open-circuit voltage is common in the literature, and might be associated with defects, surface chemistry, and resistance at various parts of the testing solar cells.

The 9.9% efficiency is by far the highest PCE in 1D DSCs. We attribute the high efficiency to at least two factors: the aggregate morphology and the partially transformed, open nanotube structures with a high surface area after calcination. Poor performance was observed if the sample was sonicated to break up the aggregates and the nanotubes. Also, previous work in hydrothermal synthesis involved pure titanate nanowires or nanoplates, or collapsed dense titania nanowires, which may not be optimum for DSC applications based on the results obtained here.

It should be noted that in the conventional DSCs based on TiO₂ nanocrystallites, a high efficiency of over 10% is usually accomplished by using a combination of the following procedures: chemical treatment to improve the interfacial adhesion and binding, the application of multiple absorption and scattering layers, antireflection substrates, or more efficient dye molecules than N719 used in this example. It is expected that incorporation of similar procedures will further improve the overall performance of the DSCs comprising the aggregate particles of TiO₂ nanomaterials of this invention. Furthermore, the hydrothermal synthesis method is simple, flexible and cost effective. Therefore, the low-cost yet high-efficiency materials of this invention will significantly reduce the manufacturing cost of DSCs for numerous applications.

It should also be noted that the aggregate particles of TiO₂ nanotubes of this example contained sodium as an impurity. Furthermore, crystalline structures other than the preferred anatase structure were present in the TiO₂ phase. Both of such characteristics may exert negative impacts on the dye loading and the charge transfer properties, and consequently limit the power conversion efficiency of DSCs. The DSCs comprising TiO₂ of anatase phase as the photoelectrode materials are known to exhibit higher PCE than those comprising TiO₂ of rutile or brookite phases. With a pure anatase phase, aggregate particles of TiO₂ nanotubes of this invention are expected to offer much high power conversion efficiency when used as the photoelectrodes in DSCs.

Synthesis of Aggregate Particles of TiO₂ Nanoparticles by an Emulsion Method. An emulsion system was prepared by mixing triton X-100 (as a surfactant), n-hexanol (as a co-surfactant), and cyclohexane (as an oil phase) in a volume ratio of 10:6:16. TiO₂ sol was prepared with 10 mL of titanium isopropoxide, 20 mL of acetic acid, and 10 mL of DI-water. 40 mL of TiO₂ sol was added to 40 mL of the emulsion system, and the mixture was stirred for 3 h at room temperature. The resulting slurry was then transferred to an autoclave for hydrothermal growth at 250° C. for 2 h. The precipitate was heated at 450° C. to remove all the organics. The resulting product was ground to a fine powder and dispersed into ethanol to create a suspension solution. Photoelectrode film was prepared by using a drop-casting method (i.e., a certain volume of solution was dispensed to the substrate by a way of drop wise addition) with the suspension solution and, finally, annealing at 450° C. for 1 h.

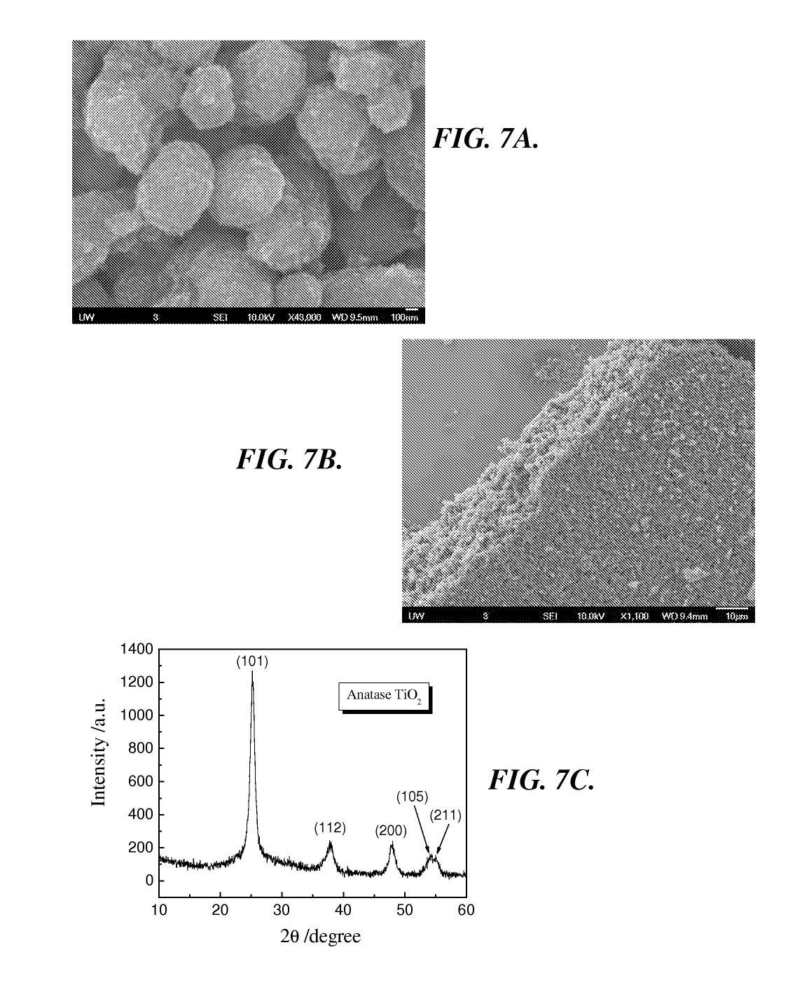

FIGS. 7A and 7B show the XRD patterns of TiO₂ aggregate particles synthesized by the emulsion method described above. The XRD pattern (7C) reveals that the aggregate particles comprise anatase structures.

A DSC was assembled and characterized by the procedure described above. An efficiency of 6.10% and fill factor of 0.59 were obtained.

It should be mentioned that the emulsion method of this invention can also be applied to the synthesis of aggregate particles from other types of nanomaterials including, but not limited to, nanoparticles, nanowires, and nanotubes.

Hydrothermal Method for the Synthesis of TiO₂ Aggregates. A precursor solution was prepared by adding 0.3 ml of titanium isopropoxide to 50 mL of 1 M oxalic acid. 10 mL of the precursor solution was removed and put into an autoclave. A FTO glass slide was placed in the 10 mL of precursor solution to serve as the substrate for the growth of aggregates. The autoclave was sealed and heated at 250° C. for 5 h. A white film formed on the part of glass substrate which was immersed in the precursor solution. The film was dried at 100° C. and annealed at 450° C. for 1 h.

One of the advantages of the hydrothermal method described above is that this method provides a very simple way for the direct formation of nanocrystal aggregates on the FTO glass substrate. Another advantage is that the size of the aggregate particles can be readily adjusted by adjusting the concentration of precursor solution, and the film thickness can be controlled by the hydrothermal growth time.

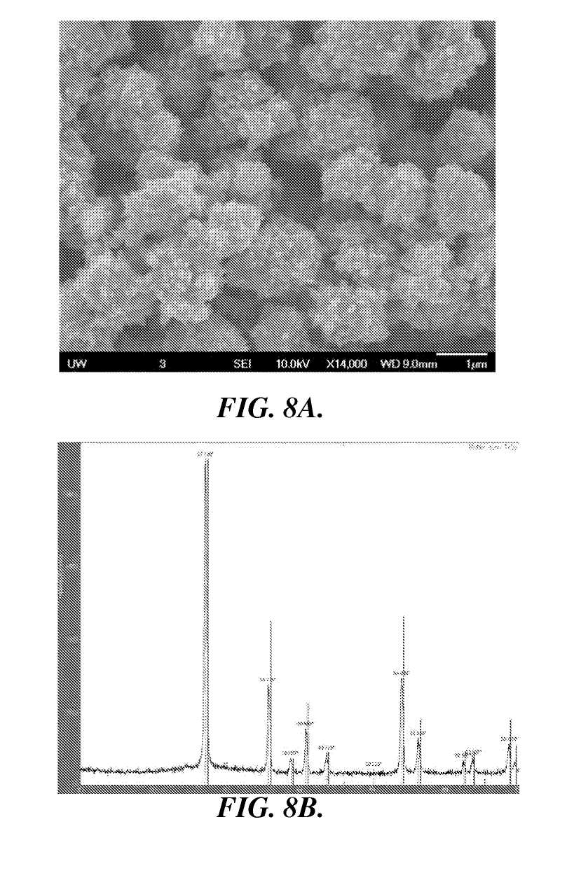

FIGS. 8A shows TiO₂ aggregate particles synthesized by the hydrothermal method described above. The XRD pattern (8B) reveals that the aggregate particles also comprise rutile structures.

A DSC was assembled and characterized by the procedure described above. An efficiency of 4.97% and fill factor of 0.55 were obtained.

As-obtained TiO₂ aggregate particles synthesized according to the procedures above appear to have a rutile phase in the crystal structure. Compared with the anatase phase TiO₂ often used in the traditional DSCs, the rutile phase TiO₂ generally has provided less advantageous performance in the dye adsorption characteristics and accordingly lead to a lower power conversion efficiency than the anatase phase TiO₂.

However, the aggregate particles of TiO₂ nanomaterials of this invention are capable of improving the performance of rutile TiO₂ nanomaterials in DSCs. Thus, this invention may lead to the development of commercially viable DSCs based on the rutile TiO₂ nanomaterials.

TiO₂ Aggregates for Dye-Sensitized Solar Cells Application. Synthesis of TiO₂ nanocrystallites: TiO₂ nanocrystallites were synthesized with a hydrothermal method using TiO₂ sol, which was typically prepared by a hydrolysis of titanium isopropoxide in deionized (DI) water in the presence of acetate acid, as described elsewhere (T. P. Chou, Q. F. Zhang and G. Z. Cao, Journal of Physical Chemistry C, 2007, 111, 18804-18811: T. P. Chou, Q. F. Zhang, B. Russo, G. E. Fryxell and G. Z. Cao, Journal of Physical Chemistry C, 2007, 111, 6296-6302).

Synthesis of TiO₂ aggregate particles: The synthesis of TiO₂ aggregates was carried out by fabricating TiO₂ spheres through admixing 1 mL of titanium isopropoxide with 30 mL of ethylene glycol and then adding into 400 mL of acetone containing 1 mL of DI-water under vigorous stirring. The precipitate of TiO₂ spheres was then treated with a reflux at 120° C. for 1.5 h in 500 mL of DI-water containing 0.5 mL of acetate acid, washed with DI-water and ethanol for several time, dried at 100° C., and finally ground to fine powder for use.

Film samples were prepared for making DSCs. Sample I refers to films consisting of TiO₂ nanocrystallites alone. Sample II was prepared to include only TiO₂ aggregates. Samples III through V are films of nanocrystallites admixed with aggregates in different ratios, specifically, 3:1 (nanocrystallites:aggregates in weight) for Sample III, 1:1 for Sample IV, and 1:3 for Sample V. All these films were prepared to be approximately 10 μm in thickness. After annealed at 450° C. for 30 min, the films were soaked in N719 dye for sensitization. The electrolyte used in this study for DSCs was made of 0.5 M tetrabutylammonium iodide, 0.1 M lithium iodide, 0.1 M iodine, and 0.5 M 4-tert-butylpyridine in acetonitrile. The solar cell performance was tested by recording the photocurrent-photovoltage behavior when the cell devices were irradiated by simulated AM 1.5 sunlight with an output power of 100 mW/cm2.

The morphology, crystalline structure and optical absorption and transmission properties of the films were characterized using SEM, XRD and UV/visible spectrometer equipped with an integrating sphere, respectively. Pore size distribution and internal surface area of aggregate powder were analyzed with a surface area and pore size analyzer (NOVA 4200e, Quantachrome Instruments, USA).

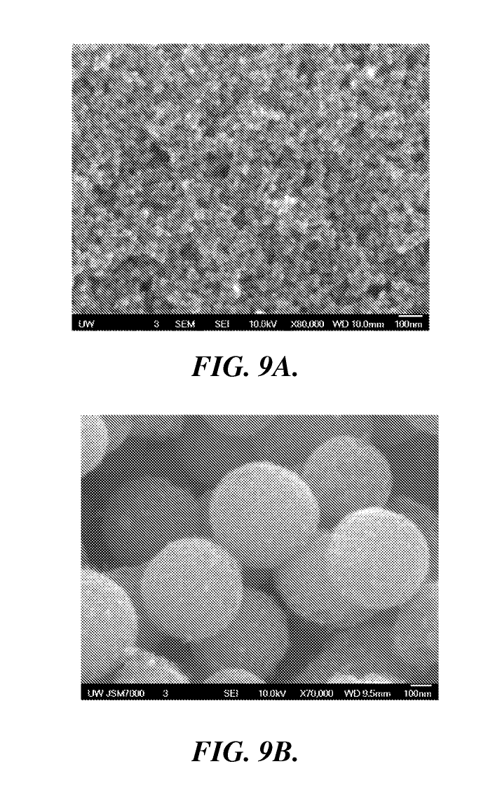

FIG. 9 shows the SEM images of TiO₂ nanocrystalline film (Samples I) and TiO₂ aggregate film (Samples II). Sample I is formed by disperse nanocrystallites in an average diameter of about 20 nm. This structure is same as that of films, for example, made of P25 powder (Degussa, Germany) in traditional DSCs. Sample II comprises spherical aggregates in submicron size. A very rough surface can be observed for these aggregates. These aggregates are assembled by nano-sized crystallites interconnected to each other and are therefore highly porous in the structure.

Specific surface areas were characterized with a Brunauer-Emmett-Teller (BET) technique, which demonstrated the specific surface areas to be approximately 100.2 m2/g for as-prepared aggregates. Such a large surface area ensures the aggregates are able to adsorb sufficient dye molecules for light harvest in DSCs. Moreover, the size of the aggregates is in the submicron meter scale, which is comparable to the wavelength of visible light and therefore, allows the aggregates to generate effective light scattering when used in sunlight irradiation.

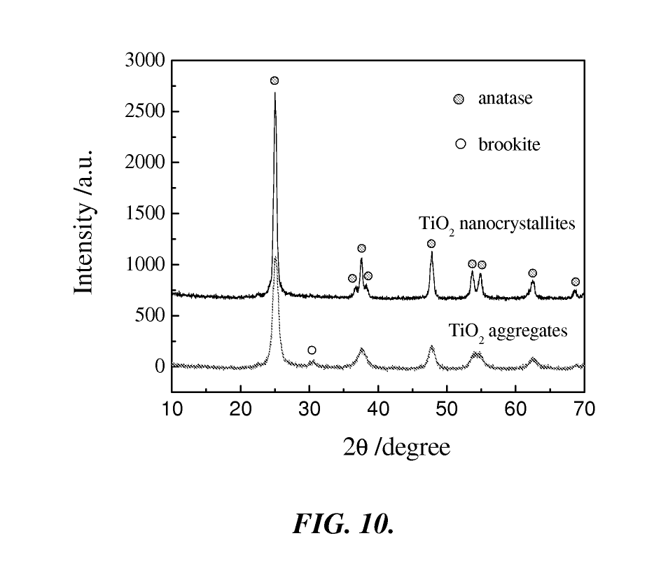

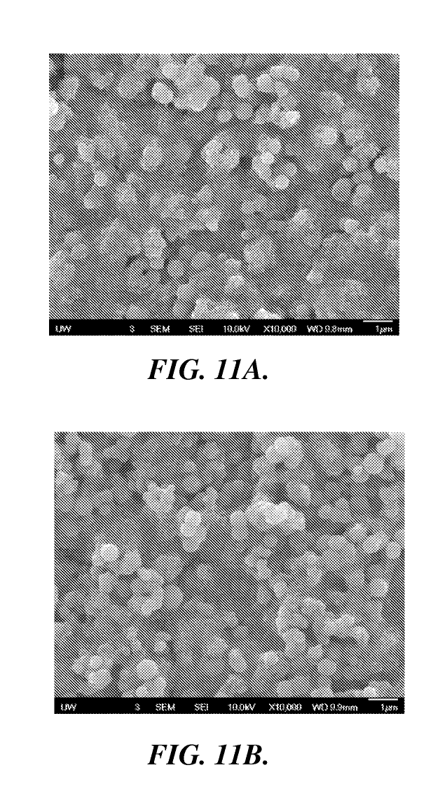

FIG. 10 shows the XRD patterns of TiO₂ films consisting of nanocrystallites or aggregates. Sample I, the nanocrystalline film, shows pure anatase phase, whereas Sample II, the aggregate film, not only contains anatase TiO₂ but also shows a small amount of brookite TiO₂. For use in DSCs, the crystal structure of TiO₂ influences the overall performance of the cells by affecting the photoelectrode film properties, including dye adsorption and/or electron injection efficiency. Anatase phase has been demonstrated to contribute to a photoelectrode film with a larger surface area while being more efficient in electron transport than the rutile or brookite phases. The difference in the crystal structure of Samples I and II is believed to arise from different synthesis routes for nanocrystallites and aggregates. In addition, with the XRD patterns shown in FIG. 10, the average crystallite sizes were estimated to be ˜18 nm for the film of nanocrystallites and ˜8 nm for the film of aggregates.

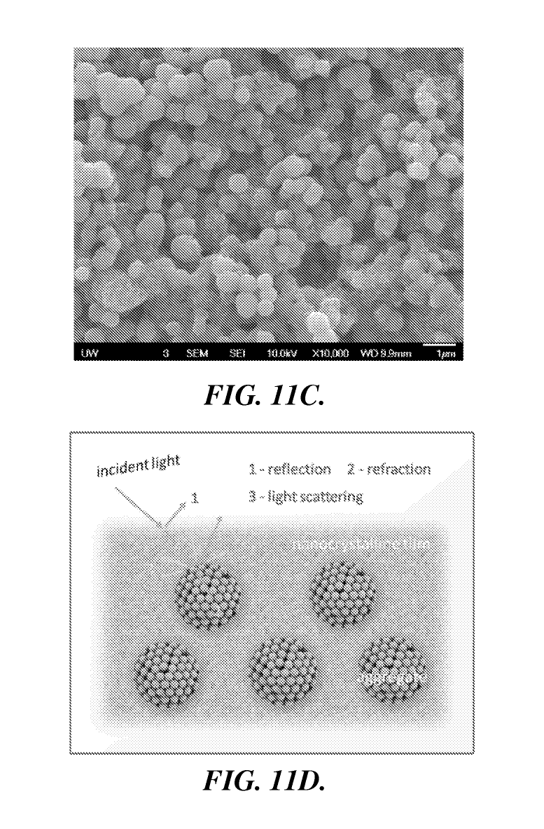

Based on the belief that as-synthesized TiO₂ aggregates are suitable as light scatterers while not reducing the internal surface area of a photoelectrode film, TiO₂ aggregates were introduced into nanocrystalline film to improve light harvesting efficiency (LHE) of the photoelectrode. FIG. 11 shows the SEM images of films consisting of nanocrystallites combined with aggregates in different ratios, 3:1 (nanocrystallites:aggregates in weight) for Sample III, 1:1 for Sample IV, and 1:3 for Sample V. The aggregates and the nanocrystallites are mixed homogeneously. Shown in FIG. 11D is a schematic drawing that demonstrates an embedded structure of TiO₂ aggregates in nanocrystalline film and the function of the TiO₂ aggregates as light scatterers.

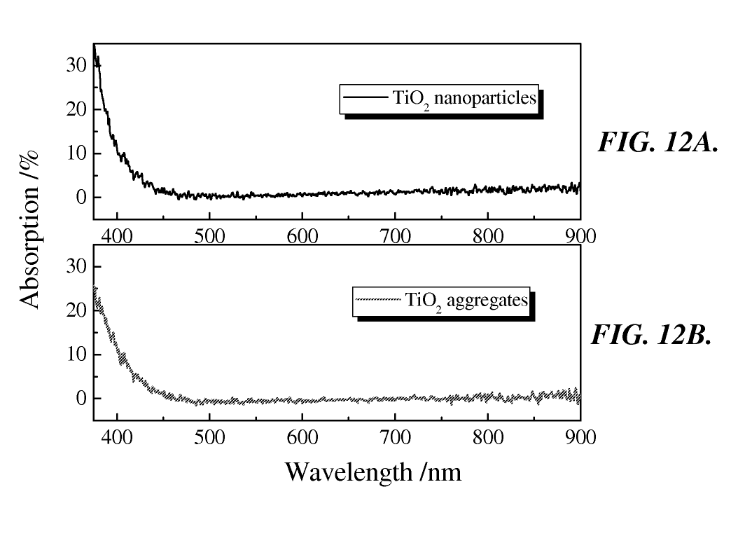

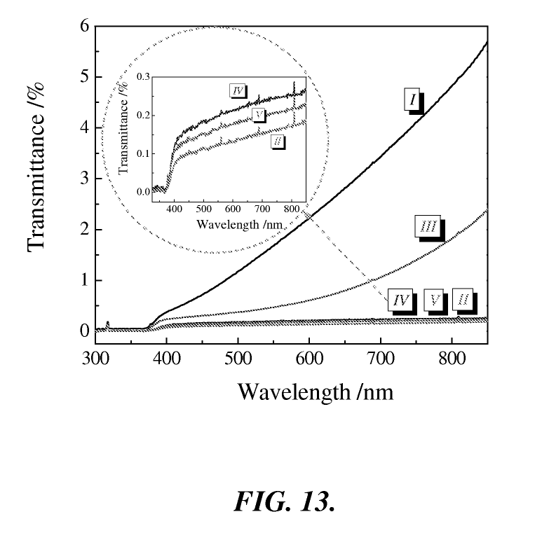

Optical absorption and transmittance spectra were employed to examine the differences in light scattering capability between the Sample III, Sample IV, and Sample V films. Shown in FIGS. 12A and 12B are the optical absorption spectra of the TiO₂ films of nanocrystallites (Sample I) (12A) and aggregates (Sample II) (12B) measured with an UV/visible spectrophotometer, which is equipped with an integrating sphere to eliminate the influence of light reflection and light scattering. The spectra present almost the same absorption profiles for these two samples in the short-wavelength region, although they are very different in the film structure. These spectra reflect an intrinsic absorption profile of TiO₂ as semiconductor materials due to the electron transition from the valence band to the conduction band (or, simply, band-to-band transition) under photoexcitation. Such a band-to-band transition can also be observed in TiO₂ aggregate particles when the influence of light reflection and light scattering is eliminated. However, although these two kinds of films are the same in their optical absorption profiles, they show an apparent difference in the film color, i.e., almost transparent for the nanocrystalline film (Sample I) but milkwhite for the film of aggregates (Sample II). Such a difference in the color can be reflected by the transmittance spectra of the films containing only nanocrystallites or aggregates, or, a mixture of nanocrystallites and aggregates. The result is shown in FIG. 13. The nanocrystalline film possesses a higher transmittance than the other films, and the film comprising of aggregates alone presents the poorest transmittance. The other films of nanocrystallites mixed with aggregates show transmittance intensities between those of the nanocrystalline film and the aggregate film, and moreover the transmittance gradually decreases as the ratio of aggregates to nanocrystallites in the films is increased. The white color of the aggregate film and the decrease in the film transmittance as percentage of the aggregates in nanocrystalline films is increased is believed to be a result of light scattering generated by the aggregates. This, in turn, demonstrates that the use of such aggregates is a practicable way of introducing light scattering into nanocrystalline film.

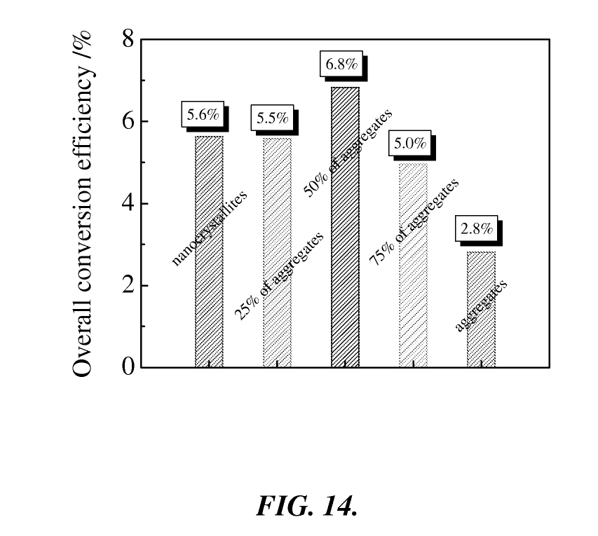

Light scattering has been demonstrated to be effective in enhancing the LHE of photoelectrode film in DSCs. This is based on a mechanism that the traveling distance of light within the photoelectrode film can be significantly extended due to the existence of light scattering. The light scattering plays a role of optical confinement or localization and thus, the photons may have a high opportunity to interact with the dye molecules and be absorbed. Shown in FIG. 14 is a schematic plot that compares the DSC conversion efficiency of the TiO₂ nanocrystalline film, the aggregate film, and the films of nanocrystallites combined with aggregates.

TABLE 2
Summary of open-circuit voltage (V_{OC}), short-circuit current
density (I_{SC}), maximum voltage (Vₘₐₓ) and current (Iₘₐₓ) output,
fill factor (FF), and overall conversion efficiency (η)
relative to the film structure of Samples I through V.

| Sample | Descrip- | V_{OC} | I_{SC} | Vₘₐₓ | Iₘₐₓ | FF | η |
|---|---|---|---|---|---|---|---|
| No. | tion | (mV) | (mA/cm²) | (mV) | (mA/cm²) | (%) | (%) |
| I | nano- | 710 | 12.01 | 535 | 10.53 | 66 | 5.6 |
| | crystallites | | | | | | |
| II | aggregates | 695 | 8.30 | 490 | 5.74 | 49 | 2.8 |
| III | 25% of | 700 | 14.60 | 470 | 11.70 | 54 | 5.5 |
| | aggregates | | | | | | |
| IV | 50% of | 710 | 14.43 | 545 | 12.54 | 67 | 6.8 |
| | aggregates | | | | | | |
| V | 75% of | 690 | 11.19 | 520 | 9.55 | 64 | 5.0 |
| | aggregates | | | | | | |

Table 2 summarizes the measured and calculated values obtained from current-voltage curves of each solar cell irradiated by an AM 1.5 simulated sunlight. The film of nanocrystallites (Sample I) reaches an efficiency of 5.6%, whereas the film of nanocrystallites combined with 50% of aggregates (Sample IV) achieved a much higher efficiency, 6.8%, which means an almost 21% increase in the conversion efficiency owing to the use of TiO₂ aggregates as scatterers in the nanocrystalline film of Sample IV. However, compared with Sample I that only contains nanocrystallites, the other films consisting of nanocrystallites combined with aggregates present a decreasing trend in the conversion efficiency, for example, 5.5% for Sample III that includes 25% of aggregates and 5.0% for Sample V that includes 75% of aggregates. Although the aggregates are also used in these two samples for a generation of light scattering, it seems that a light scattering enhancement effect may be counteracted due to an unsuitable facet of the crystallites of aggregates, which causes low density adsorption of the dye molecules and therefore, on one hand may improve the light harvest by light scattering, but on the other hand may simultaneously give rise to insufficient optical absorption due to decreased dye adsorption. This is also manifested by Sample II that comprises of aggregates alone and shows relatively low conversion efficiency, only 2.8%. In addition, the low conversion efficiency of Sample II is also believed to be a result of loosely organized structure of the aggregate film that leads to an unavoidable loss in the surface area of the photoelectrode film.

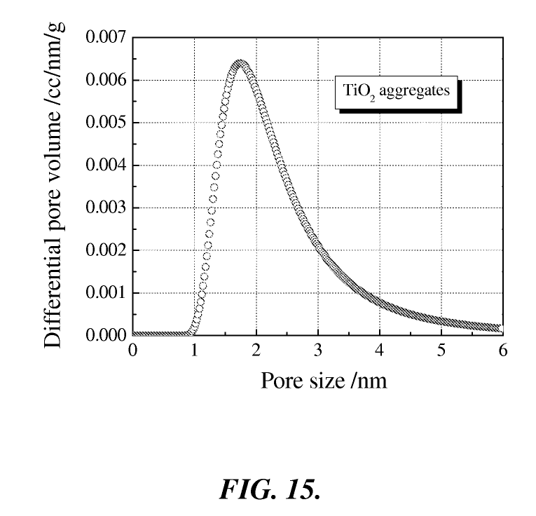

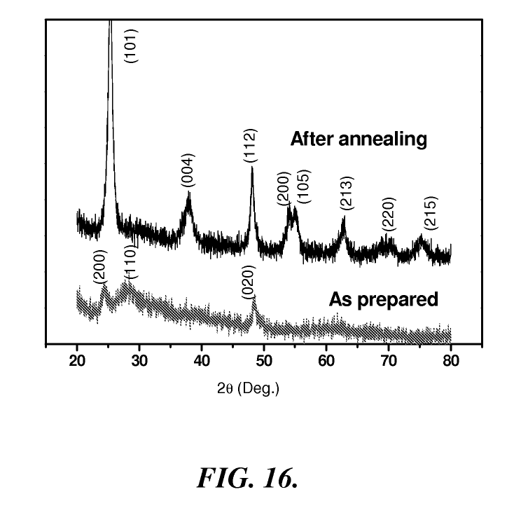

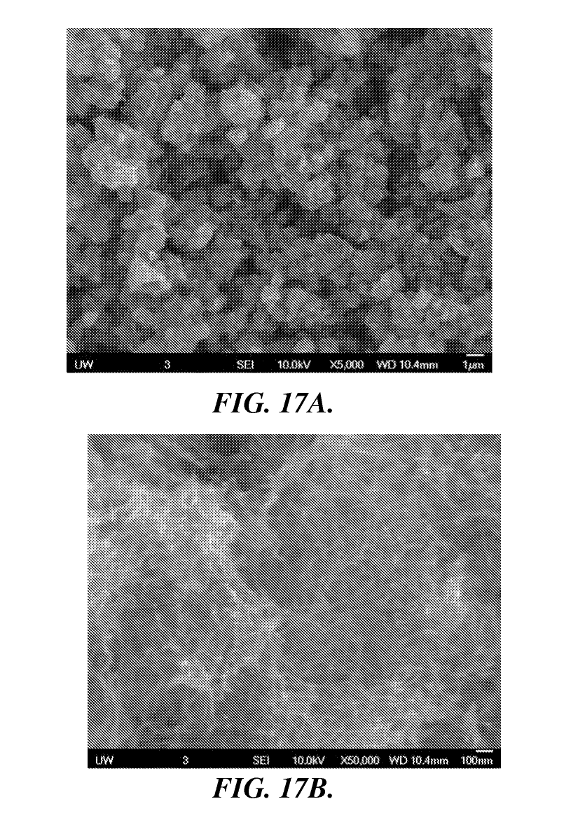

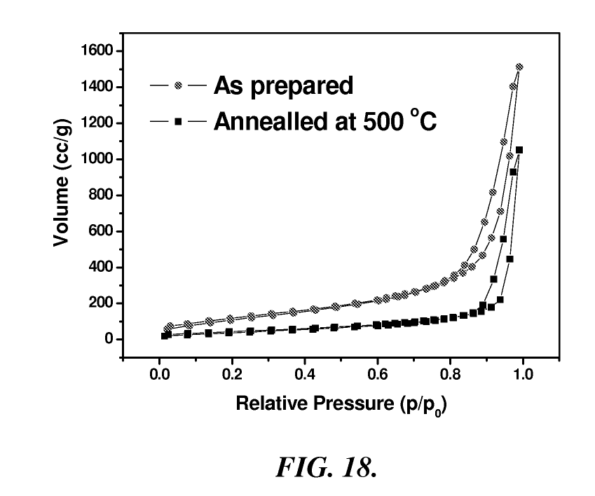

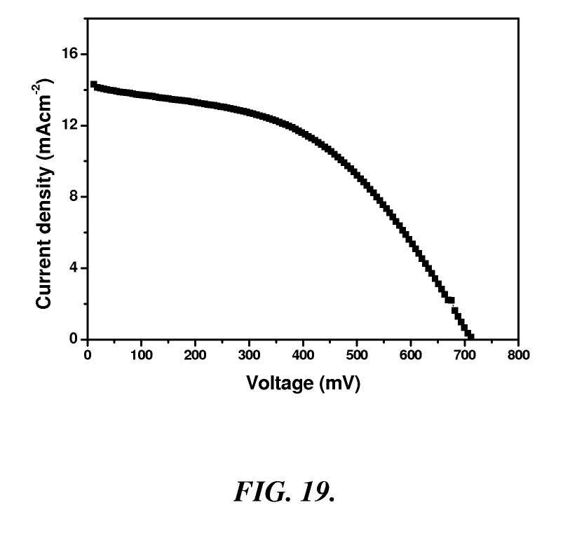

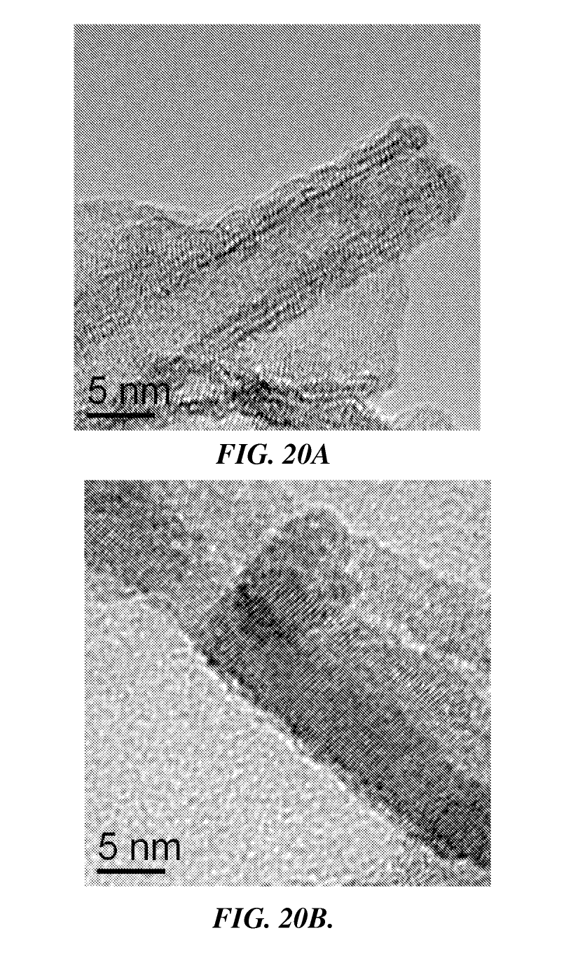

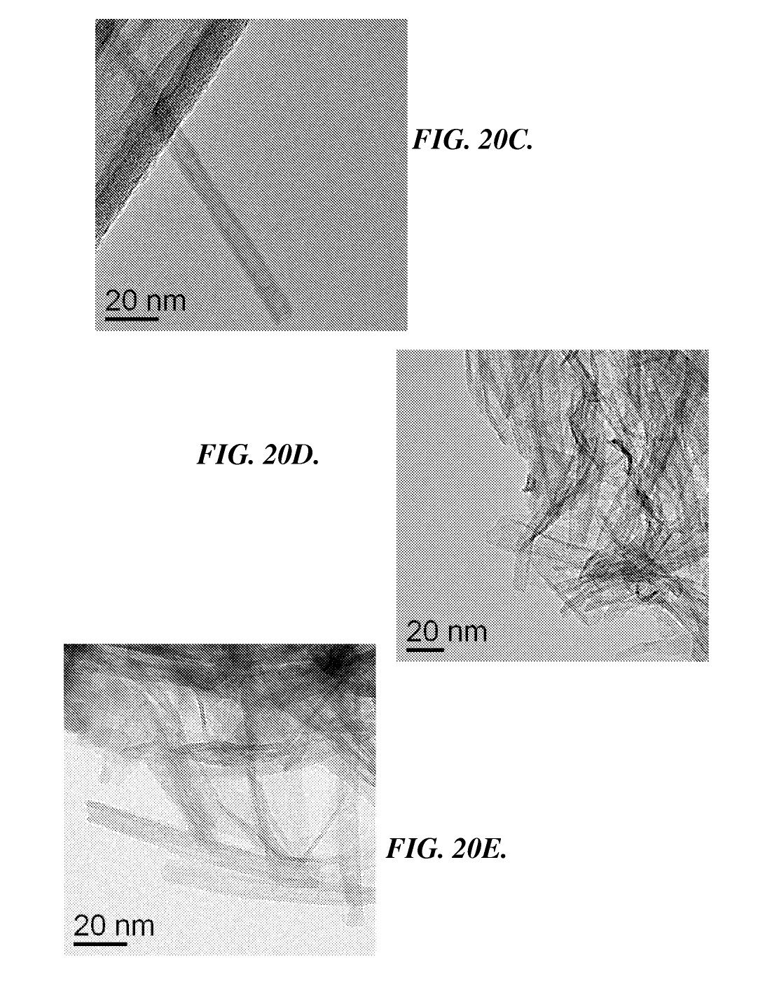

Besides the unsatisfying crystal structure and film packing density, too small pore size of the aggregates is also thought to be a reason that restricts both the filtration of dye molecules and the diffusion of electrolyte when the solar cell is under operating conditions. FIG. 15 shows the pore size distribution measured with a BET technique for TiO₂ aggregates. The pores of TiO₂ aggregates range from 1 nm to approximately 6 nm with the peak around 1.8 nm.

Carbon Sphere-Templated Synthesis of TiO₂ Aggregates. Micron or submicron-sized aggregate particles consisting of nanoparticles or nanowires are new types of nanostructured materials having a large specific surface area which can act as effective light harvesting materials for the photoelectrode of DSCs. In this example, TiO₂ aggregate particles are fabricated by a hydrothermal growth method that utilizes the in situ formed colloidal carbon spheres as templates.

The synthesis started from the preparation of a TiO₂ sol by adding 2.5 mL of titanium alkoxide into an aqueous solution containing 5 mL of hydrochloric acid (HCl), 5 mL of ethanol, and 0.005 mol of sucrose as sugar. The sol was sequentially transferred to an autoclave for hydrothermal growth at 100-250° C. for 10 h. After the reaction, the precipitate, comprising a composite of TiO₂ and the carbon formed from sucrose, was washed with DI water. The product was then heated at 500° C. for 3 h in air to remove the carbon from the product, yielding a powder of TiO₂ aggregate particles. As-obtained TiO₂ aggregate particles were observed to be spherical in shape with a diameter in the range of 300 nm-1.5 μm. The TiO₂ aggregate particles comprised numerous nano-sized TiO₂ crystallites.

The spherical morphology of the aggregate particles resulted from the simultaneous hydrolysis of sucrose and titanium alkoxide, leading to the formation of submicron carbon spheres embedded with TiO₂ nanocrystallites. The size distribution of the TiO₂ aggregate particles was found to be influenced by: (1) the pH value of the precursor sol; (2) the concentration of sucrose in the solution; and (3) the temperature for hydrothermal growth. An XRD characterization indicated that these TiO₂ aggregate particles comprised the anatase phase.

Mesoporous TiO₂ Spheres for Dye-Sensitized Solar Cell and Photocatalyst Application. The synthesis of TiO₂ aggregate particles of this example involves a solvothermal reaction of titanium alkoxide in a non-volatile solvent such as diethylene glycol (DEG) under an acidic condition. An example of such synthesis is as follows.

3 mL of titanium alkoxide was added into a solution containing 45 mL of DEG, 5 mL of hydrochloride acid (HCl), and 5 mL of water. The pH value of the solution was found to be less than 2. This mixture was put in an oil bath and then heated at a temperature above 100° C. for 1 h. This reaction led to the formation of a white colloidal suspension. Subsequent treatment with repeated centrifugation and washing was applied, yielding approximately 0.8 g of powdery TiO₂ aggregate particles in the form of mesoporous spheres.

This method made use of a non-volatile solvent, such as DEG, to provide a temperature higher than 100° C. for the hydrolysis of titanium alkoxide at ambient pressure. The acid was employed to suppress the hydrolysis occurring at low temperatures. The type of acid used in this sort of synthesis is not limited to HCl, and other acids such as acetic acid (HAc), oxalic acid, nitric acid (HNO₃), and others can also be used.

As-synthesized TiO₂ aggregate particles were observed to be submicron-sized spheres with a highly mesoporous structure. The crystal phase of the TiO₂ was controlled by choosing the kind and amount of acid, the precursor type and concentration, and the reaction conditions.

The TiO₂ aggregate particles of this example exhibited an excellent performance as the photoelectrode of DSCs. These materials may also be used for photocatalyst applications as well as for light scattering additives in numerous applications.

Synthesis of anatase TiO₂ nanotube aggregates. Commercial grade, nanosized TiO₂ (Degussa Aeroxide P25), which consists of ca. 30% rutile and 70% anatase, was a gift from Degussa Corp. (Parsippany, N.J.) and used without any purification or treatment. The preparation was initiated by adding 1.0 g Dugussa Aeroxide P25 powder into a 40 mL aqueous solution of 10 M sodium hydroxide. After sonication for 30 min, this suspension was put into a Teflon-lined autoclave and heated to 150-170° C. for 12-36 h with a heating rate of 5-10° C./min. The products were added into 60-100 mL hydrochloride (HCl) solutions (0.1 M) and stirred for 1-3 h at room temperature. The products were further treated with HCl washing followed by centrifuge at 3000 RPM. This acid washing was repeated several times until the pH of the suspension reached ˜3-5. The resulting powder with acid washing was washed in a centrifuge tube with 20-40 mL ethanol. The ethanol wash was repeated several times until all particles dispersed in the suspension. The final product was obtained by heat treating the resultant powder at 500° C. for 2 h in air.

TABLE 3
Summary of the surface area, average pore size, and pore volume
of the TiO₂ nanotube before and after annealing at 500° C.

| | Surface Area | Average Pore | Pore Volume |
|---|---|---|---|
| | (m²/g) | Size (nm) | (cc/g) |
| As prepared | 445 | 5.39 | 2.3 |
| 500° C. | 164 | 5.35 | 1.618 |
| Annealing | | | |

While illustrative embodiments have been illustrated and described, it will be appreciated that various changes can be made therein without departing from the spirit and scope of the invention.

The embodiments of the invention in which an exclusive property or privilege is claimed are defined as follows:

1. Aggregate particles comprising titanium dioxide (TiO₂) nanotubes.

2. The aggregate particles of claim 1, wherein the nanotubes comprise substantially crystalline structures.

3. The aggregate particles of claim 2, wherein the crystalline structures comprise the anatase phase, the rutile phase, or mixtures of the anatase phase and the rutile phase.

4. The aggregate particles of claim 1, wherein the nanotubes have a length from about 0.1 nm to 100 μm.

5. The aggregate particles of claim 1 having a surface area from about 1 cm²/g to about 1,000 m²/g.

6. The aggregate particles of claim 1 further comprising a titanium dioxide nanomaterial or a titanium dioxide nanomaterial precursor.

7. The aggregate particles of claim 6, wherein the nanomaterial is selected from the group consisting of a nanotube, a nanoparticle, and mixtures thereof.

8. A method of forming aggregate particles of titanium dioxide nanotubes, comprising:
(a) transforming a titanium dioxide nanomaterial precursor to a titanium dioxide nanotube; and
(b) forming aggregate particles of titanium dioxide nanotubes from the titanium dioxide nanomaterial precursor.

9. The method of claim 8, wherein forming the aggregate particles comprises contacting with ethanol.

10. The method of claim 9, wherein forming the aggregate particles comprises contacting with hydrochloric acid after contacting with ethanol.

11. The method of claim 8, wherein transforming a titanium dioxide nanomaterial precursor to a titanium dioxide nanotube comprises forming an emulsion of the titanium dioxide nanomaterial precursor.

12. The method of claim 8, wherein forming aggregate particles of titanium dioxide nanotubes comprises a hydrothermal method.

13. A method of forming aggregate particles of titanium dioxide nanomaterials, comprising:
(a) transforming a titanium dioxide nanomaterial precursor to a titanium dioxide nanomaterial sol;
(b) combining the sol with an oil to provide an emulsion; and
(c) forming aggregate particles of titanium dioxide nanomaterials from the emulsion by a hydrothermal method.

14. The method of claim 13, wherein forming aggregate particles from the emulsion comprises a hydrothermal method.

15. The method of claim 13, wherein forming aggregate particles from the emulsion comprises a solvothermal method.

16. A method of forming aggregate particles of titanium dioxide nanomaterials, comprising:
(a) transforming a titanium dioxide nanomaterial precursor to a titanium dioxide nanomaterial; and
(b) forming aggregate particles of titanium dioxide nanomaterials from the titanium dioxide nanomaterial precursor in the presence of a template, preferably a carbon sphere template.

17. A method of forming a photoelectrode of a solar cell, comprising depositing a plurality of the aggregate particles of claim 1 on a substrate.

18. A method of forming a photoelectrode of a solar cell, comprising depositing a plurality of aggregate particles of a titanium dioxide nanomaterial on a substrate.

19. The method of claim 18, wherein the titanium dioxide nanomaterial is selected from the group consisting of a nanotube, a nanoparticle, and mixtures thereof.

20. The method of claim 18 further comprising depositing a titanium dioxide nanomaterial.

21. A photoelectrode for a solar cell, comprising:
(a) a substrate; and
(b) a layer on a surface of the substrate, wherein the layer comprises aggregate particles of titanium dioxide nanomaterials.

22. A solar cell, comprising the photoelectrode of claim 21.
